(19) United States
(12) Patent Application Publication
(10) Pub. No.: US 2025/0029885 A1
(43) Pub. Date: Jan. 23, 2025

(54) SEMICONDUCTOR PACKAGE AND METHODS OF FORMING THE SAME

(71) Applicant: Samsung Electronics Co., Ltd., Suwon-si (KR)

(72) Inventor: Donggyu Kim, Suwon-si (KR)

(21) Appl. No.: 18/416,151

(22) Filed: Jan. 18, 2024

(30) Foreign Application Priority Data
Jul. 19, 2023 (KR) 10-2023-0094048
Aug. 11, 2023 (KR) 10-2023-0105773

(51) Int. Cl. H01L 23/36; H01L 23/00; H01L 23/38; H01L 23/498; H01L 23/538; H01L 23/64

(52) U.S. Cl. CPC H01L 23/36; H01L 23/38; H01L 23/49816; H01L 23/5383; H01L 23/5386; H01L 23/642; H01L 24/16; H01L 24/48; H01L 2224/16227; H01L 2224/48227

(57) ABSTRACT

A semiconductor package may include a package substrate, a semiconductor chip on the package substrate, and one or more outer terminals below the package substrate. The one or more outer terminals may include at least one signal terminal delivering an operation signal to the semiconductor chip and at least one power terminal supplying an electric power to the semiconductor chip. The package substrate may include an insulating portion, one or more interconnection patterns provided in the insulating portion to electrically connect the semiconductor chip to the at least one signal terminal, and a heat-dissipation pattern provided in the insulating portion to electrically connect the semiconductor chip to the at least one power terminal. The heat-dissipation pattern may include at least one conductive pattern and at least one thermoelectric pattern, which are connected in series in a direction from the one or more outer terminals toward the semiconductor chip.

### CROSS-REFERENCE TO RELATED APPLICATIONS

This U.S. non-provisional patent application claims priority under 35 U.S.C. § 119 to Korean Patent Application Nos. 10-2023-0094048 and 10-2023-0105773, filed on Jul. 19, 2023 and Aug. 11, 2023, respectively, in the Korean Intellectual Property Office, the entire contents of which are hereby incorporated by reference.

### BACKGROUND OF THE INVENTION

The present disclosure relates to a semiconductor package, and in particular, to an interconnection substrate with a penetration via and a semiconductor package including the interconnection substrate.

In light of recent advancements in the electronics industry, the demand for high-performance, high-speed, and compact electronic components has been steadily increasing. As a result, there is a development of packaging technologies that allow for the mounting of multiple semiconductor chips within a single package.

Recently, a demand for portable electronic devices has been rapidly increasing in the market, and thus, it is necessary to reduce sizes and weights of electronic components constituting the portable electronic devices. For this, it is necessary to develop packaging technologies that reduce the size and weight of each component and integrate a plurality of individual components into a single package.

A thermoelectric device is a device converting a heat energy to an electric energy. The thermoelectric device has been receiving a lot of attention due to recent clean energy-oriented policies. In the 1800s, the thermoelectric effect was discovered by Thomas Johann Seebeck. Specifically, Seebeck connected patterns of bismuth and copper, placing a compass needle between them. When one side of the bismuth pattern was exposed to heat, Seebeck observed the emergence of the thermoelectric effect. This effect manifested as a magnetic field, which, in turn, induced motion in the compass needle due to the current generated by the temperature difference.

### SUMMARY

Embodiments of the present inventive concept provide a semiconductor package with improved heat-dissipation efficiency.

Embodiments of the present inventive concept provide a semiconductor package with improved electrical characteristics.

According to embodiments of the present inventive concept, a semiconductor package may include a package substrate, a semiconductor chip mounted on the package substrate, and one or more outer terminals provided below the package substrate. The one or more outer terminals may include at least one signal terminal configured to deliver an operation signal to the semiconductor chip, and at least one power terminal configured to supply electrical power to the semiconductor chip. The package substrate may include an insulating portion, one or more interconnection patterns provided in the insulating portion to electrically connect the semiconductor chip to the at least one signal terminal, and a heat-dissipation pattern provided in the insulating portion to electrically connect the semiconductor chip to the at least one power terminal. The heat-dissipation pattern may include at least one conductive pattern and at least one thermoelectric pattern, connected in series in a direction from the one or more outer terminals toward the semiconductor chip. The at least one conductive pattern and the at least one thermoelectric pattern may be alternately connected to each other, and the at least one thermoelectric pattern may include an n-type semiconductor material.

According to embodiments of the present inventive concept, a semiconductor package may include a package substrate, a semiconductor chip mounted on the package substrate, and one or more outer terminals provided below the package substrate. The package substrate may include an insulating portion, a plurality of first pads provided on a top surface of the insulating portion, and on which the semiconductor chip is mounted, a plurality of second pads and a third pad provided on a bottom surface of the insulating portion and coupled to the one or more outer terminals, one or more interconnection patterns provided in the insulating portion to connect the plurality of first pads to the plurality of second pads, and a heat-dissipation pattern disposed in the insulating portion and on the third pad. The heat-dissipation pattern may include at least one conductive pattern and at least one thermoelectric pattern vertically and alternately stacked on the third pad. The at least one conductive pattern may include a same material as the one or more interconnection patterns, and an end portion of the heat-dissipation pattern residing adjacent to the semiconductor chip may be configured to be cooled when a voltage is applied to the third pad.

According to embodiments of the present inventive concept, a semiconductor package may include a package substrate, an interposer substrate disposed on the package substrate, a first semiconductor chip mounted on the interposer substrate, and a chip stack provided on the interposer substrate and spaced apart from the first semiconductor chip. The chip stack may include a plurality of second semiconductor chips vertically stacked on the interposer substrate. The interposer substrate may include one or more interconnection patterns configured to deliver an operation signal from the package substrate to the first semiconductor chip and the chip stack, one or more heat-dissipation patterns configured to deliver electrical power from the package substrate to the first semiconductor chip or the chip stack, the one or more heat-dissipation patterns including at least one conductive pattern and at least one thermoelectric pattern alternately disposed and connected in series in a direction perpendicular to the interposer substrate, and a capacitor pattern electrically connected to the at least one conductive pattern. The at least one conductive pattern may include a same material as the one or more interconnection patterns, and the at least one thermoelectric pattern may include an n-type semiconductor material.

### BRIEF DESCRIPTION OF THE DRAWINGS

FIG. 1 is a sectional view illustrating a semiconductor package according to some embodiments of the present inventive concept.

FIGS. 2 to 4 are enlarged sectional views of the semiconductor package illustrating a portion ‘A’ of FIG. 1 according to some embodiments of the present inventive concept.

FIG. 5 is a sectional view illustrating a semiconductor package according to some embodiments of the present inventive concept.

FIG. 6 is an enlarged sectional view of the semiconductor package illustrating a portion ‘B’ of FIG. 5 according to some embodiments of the present inventive concept.

FIG. 7 is a sectional view illustrating a semiconductor package according to some embodiments of the present inventive concept.

FIG. 8 is an enlarged sectional view of the semiconductor package illustrating a portion ‘C’ of FIG. 7 according to some embodiments of the present inventive concept.

FIGS. 9 and 10 are sectional views illustrating a semiconductor package according to some embodiments of the present inventive concept.

FIG. 11 is a sectional view illustrating a semiconductor module according to some embodiments of the present inventive concept.

FIG. 12 is a sectional view illustrating a semiconductor package according to some embodiments of the present inventive concept.

FIGS. 13 and 14 are enlarged sectional views of the semiconductor package illustrating a portion ‘D’ of FIG. 12 according to some embodiments of the present inventive concept.

FIGS. 15 and 16 are enlarged sectional views of the semiconductor package illustrating a portion ‘E’ of FIG. 12 according to some embodiments of the present inventive concept.

FIGS. 17 to 20 are sectional views illustrating a semiconductor package according to some embodiments of the present inventive concept.

FIGS. 21 to 30 are sectional views illustrating a method of fabricating a semiconductor package according to some embodiments of the present inventive concept.

### DETAILED DESCRIPTION

Example embodiments of the present inventive concepts will now be described more fully with reference to the accompanying drawings, in which example embodiments are shown.

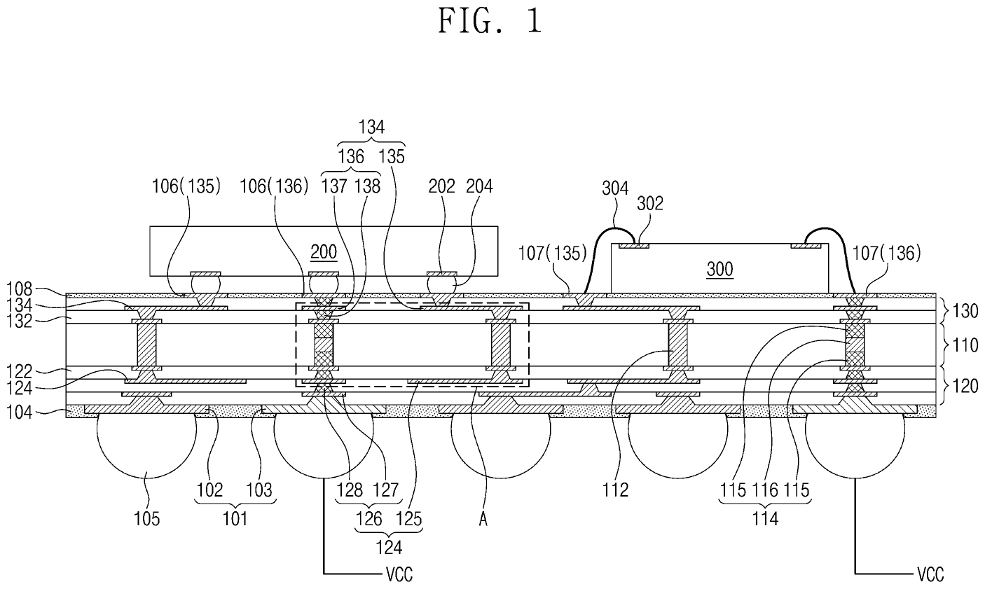

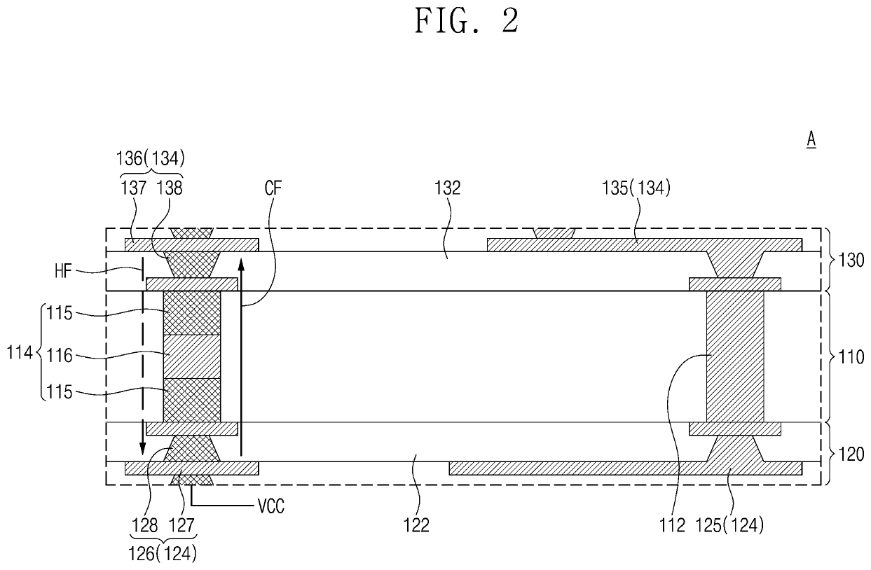

FIG. 1 is a sectional view illustrating a semiconductor package according to some embodiments of the present inventive concept. FIGS. 2 to 4 are enlarged sectional views of the semiconductor package illustrating a portion ‘A’ of FIG. 1.

Referring to FIGS. 1 and 2, a package substrate 100 may be provided. The package substrate 100 may include a core portion 110, a lower buildup portion 120 disposed on a bottom surface of the core portion 110, and an upper buildup portion 130 disposed on a top surface of the core portion 110.

The core portion 110 may be extended in a specific direction. The core portion 110 may include one or more core patterns, when viewed in a plan view. The core portion 110 is illustrated to have one core pattern, but the present inventive concept is not limited to this example. For example, in some embodiments, the core portion 110 may include two or more core patterns. That is, the package substrate 100 may include a plurality of core patterns, which are horizontally spaced apart from each other. The core portion 110 may constitute at least a portion of an insulating portion of the package substrate 100. The core portion 110 may include an insulating material. For example, in some embodiments, the core portion 110 may include at least one of glass fiber, ceramic plate, and epoxy regions. Alternatively, the core portion 110 may be formed of or include at least one of stainless steel, aluminum (Al), nickel (Ni), magnesium (Mg), zinc (Zn), tantalum (Ta), and/or combinations thereof.

In some embodiments, the core portion 110 may include first vertical interconnection patterns 112 and second vertical interconnection patterns 114, which are provided to vertically penetrate the core portion 110. The first and second vertical interconnection patterns 112 and 114 may extend from the bottom surface of the core portion 110 toward the top surface of the core portion 110. The first and second vertical interconnection patterns 112 and 114 may be exposed to the outside of the core portion 110 near the top and bottom surfaces of the core portion 110. The first and second vertical interconnection patterns 112 and 114 may be horizontally spaced apart from each other. As used herein, the terms ‘horizontal’ or ‘horizontally’ represent a direction that is parallel to the top surface of the package substrate 100. As an example, in some embodiments, the first and second vertical interconnection patterns 112 and 114 may be spaced apart from each other in a direction that is parallel to the top surface of the core portion 110.

The first vertical interconnection patterns 112 may electrically connect the upper buildup portion 130 to the lower buildup portion 120. For example, in some embodiments, the first vertical interconnection patterns 112 may be one or more interconnection patterns, which are provided in the package substrate 100 and are used to deliver operation signals to a first or second semiconductor chip 200 or 300 to be described below. The first vertical interconnection pattern 112 may be a conductive pillar, which is extended in a vertical direction. The first vertical interconnection patterns 112 may be formed of or include at least one metallic material (e.g., copper (Cu) or tungsten (W)).

The second vertical interconnection patterns 114 may thermally connect the upper buildup portion 130 to the lower buildup portion 120. For example, in some embodiments, the second vertical interconnection patterns 114 may be a heat-dissipation pattern, which is used to transfer heat, which is generated in the first or second semiconductor chip 200 or 300, to an underlying structure residing below the package substrate 100. In addition, the second vertical interconnection patterns 114 may electrically connect the upper buildup portion 130 to the lower buildup portion 120. For example, in some embodiments, the second vertical interconnection patterns 114 may be one or more interconnection patterns, which are placed in the package substrate 100 and are used to deliver a power signal or a ground signal to the first or second semiconductor chip 200 or 300. The second vertical interconnection patterns 114 may include at least one thermoelectric pattern 115 and at least one conductive pattern 116. Hereinafter, the thermoelectric pattern 115 and the conductive pattern 116 will be described with reference to one of the second vertical interconnection patterns 114.

In some embodiments, the thermoelectric patterns 115 may be vertically arranged. As used herein, the terms ‘vertical’ or ‘vertically’ represent a direction that is perpendicular to the top surface of the package substrate 100. As an example, in some embodiments, the thermoelectric patterns 115 may be spaced apart from each other in a direction that is perpendicular to the top surface of the core portion 110. FIGS. 1 and 2 illustrate an example according to some embodiments of the present inventive concept, in which two thermoelectric patterns 115 are provided in one of the second vertical interconnection patterns 114, but the present inventive concept is not limited to this example. As another example, in some embodiments, at least one of the second vertical interconnection patterns 114 may be configured to include three or more thermoelectric patterns 115. The thermoelectric patterns 115 may be formed of or include an n-type semiconductor material or an n-type thermoelectric conversion pattern.

In some embodiments, the conductive pattern 116 may be disposed between the thermoelectric patterns 115. That is, the conductive pattern 116 may connect the vertically-separated thermoelectric patterns 115 to each other. FIGS. 1 and 2 illustrate an example according to embodiments of the present inventive concept, in which one conductive pattern 116 is provided in each of the second vertical interconnection pattern 114, but the present inventive concept is not limited to this example. In another embodiment, the number of the conductive pattern 116 may be one less than the number of the thermoelectric patterns 115, and each of the conductive patterns 116 may be disposed between adjacent thermoelectric patterns 115. That is, the thermoelectric patterns 115 and the conductive patterns 116 may be alternatively disposed such that they are connected in series. Here, in some embodiments, a pair of the thermoelectric patterns 115 may be respectively disposed as the topmost and bottommost portions of the second vertical interconnection pattern 114. A thickness of the conductive pattern 116 may be larger than a thickness of the thermoelectric pattern 115. The conductive pattern 116 may include the same material as the first vertical interconnection patterns 112. For example, in some embodiments, the conductive pattern 116 may be formed of or include at least one metallic material (e.g., copper (Cu) or tungsten (W)).

In some embodiments, a heat-dissipation pattern (i.e., the second vertical interconnection patterns 114) is provided in the core portion 110 of the package substrate 100, and may serve as a thermoelectric device. For example, in some embodiments, as shown in FIG. 2, when there is a current flow CF passing through the second vertical interconnection patterns 114 in an upward direction, a heat flow HF may be produced to pass through the second vertical interconnection patterns 114 in an opposite, downward direction. In detail, when there is a current flow CF, the thermoelectric patterns 115 may produce a heat flow HF, and the thermoelectric patterns 115 may be connected in series, because the conductive pattern 116 is placed between the thermoelectric patterns 115 to electrically connect the thermoelectric patterns 115 to each other.

According to some embodiments of the present inventive concept, the elements of the second vertical interconnection patterns 114 (i.e., the thermoelectric patterns 115 and the conductive pattern 116) serving as the thermoelectric device may be vertically arranged and aligned to each other. Thus, each of the second vertical interconnection patterns 114 may occupy a small area, thereby it may be possible to reduce an area for the thermoelectric device and overall size of the semiconductor package.

In addition, the second vertical interconnection patterns 114 may be provided to vertically penetrate the core portion 110 from top to bottom. Thus, the second vertical interconnection patterns 114 may be used to easily transfer heat from the top of the core portion 110 to the bottom of the core portion 110. As a result, a semiconductor package with improved heat-dissipation efficiency may be provided.

In some embodiments, the lower buildup portion 120 may be disposed on the bottom surface of the core portion 110. The lower buildup portion 120 may cover the bottom surface of the core portion 110. The lower buildup portion 120 may include one or more first interconnection layers, which are sequentially stacked on the bottom surface of the core portion 110. Each of the first interconnection layers may include a lower insulating pattern 122 and lower interconnection patterns 124 in the lower insulating pattern 122. That is, the lower buildup portion 120 may include the lower insulating patterns 122, which are sequentially stacked, and the lower interconnection patterns 124, which are provided in the lower insulating patterns 122. The lower interconnection patterns 124 in one of the first interconnection layers may be electrically connected to the lower interconnection patterns 124 in another first interconnection layer adjacent thereto. Hereinafter, the lower insulating pattern 122 and the lower interconnection patterns 124 will be described in more detail with reference to one of the first interconnection layers.

The lower insulating pattern 122 may constitute at least a portion of an insulating portion of the package substrate 100. In some embodiments, the lower insulating pattern 122 may be formed of or include at least one of prepreg, Ajinomoto build-up film (ABF), FR-4, and/or bismaleimide triazine (BT).

The lower interconnection patterns 124 may be provided in an upper portion of the lower insulating pattern 122. The lower interconnection patterns 124 may be exposed to a top surface of the lower insulating pattern 122. Top surfaces of the lower interconnection patterns 124 may be coplanar with the top surface of the lower insulating pattern 122. In some embodiments, the lower interconnection patterns 124 may not be exposed to a bottom surface of the lower insulating pattern 122. That is, the lower interconnection patterns 124 may be disposed on the bottom surface of the core portion 110 or the bottom surface of another one of the first interconnection layers, and the lower insulating pattern 122 may cover the lower interconnection patterns 124, on the bottom surface of the core portion 110 or the bottom surface of the another one of the first interconnection layers. The lower interconnection patterns 124 may extend horizontally in the lower insulating pattern 122. As described above, the lower interconnection patterns 124 may serve as pad or wire portions of the first interconnection layer.

Each of the lower interconnection patterns 124 may have a damascene structure. For example, in some embodiments, the lower interconnection pattern 124 may include a via portion that extends upward from a top surface thereof. The via portion may be used to vertically connect the lower interconnection patterns 124 of the first interconnection layers, which are adjacent to each other. For example, in some embodiments, the via portion may extend vertically from the top surface of the lower interconnection patterns 124 to penetrate the lower insulating pattern 122 of another one of the first interconnection layers thereon and may be coupled to a bottom surface of the lower interconnection patterns 124 of the another one of the first interconnection layers. In other words, a lower portion of the lower interconnection pattern 124, which is placed in the lower insulating pattern 122, may be a head portion that is used as a horizontal line or a pad, and the via portion of the lower interconnection pattern 124 may be a tail portion. In some embodiments, the lower interconnection patterns 124 may have an inverted shape of the letter ‘T’. The via portion of the lower interconnection pattern 124 may decrease in width as a distance to the core portion 110 decreases. That is, the via portion of the lower interconnection pattern 124 may have a tapered shape.

The lower interconnection patterns 124 of the uppermost one of the first interconnection layers, which is in direct contact with the core portion 110, may not have the via portion. In other words, the lower interconnection patterns 124 of the uppermost one of the first interconnection layers may have only the head portion. In detail, a top surface of the uppermost one of the lower interconnection patterns 124 may be coplanar with a top surface of the uppermost one of the lower insulating pattern 122. The uppermost one of the lower interconnection patterns 124 may be connected to the bottom surface of the core portion 110 (e.g., the bottom surfaces of the first and second vertical interconnection patterns 112 and 114).

The lower interconnection patterns 124 may include first lower interconnection patterns 125 and second lower interconnection patterns 126.

The first lower interconnection patterns 125 may be interconnection patterns of the lower interconnection patterns 124, which are directly or electrically connected to the first vertical interconnection patterns 112. For example, in some embodiments, the first lower interconnection patterns 125 may be one or more interconnection patterns, which are used to deliver operation signals to the first or second semiconductor chip 200 or 300. The via portion of the first lower interconnection pattern 125 may decrease in width as a distance to the core portion 110 decreases. For example, in some embodiments, the via portion of the first lower interconnection pattern 125 may have a tapered shape. As shown in FIGS. 1 and 2, in some embodiments, the first lower interconnection patterns 125, which are electrically connected to each other, may not be vertically aligned to each other. As an example, in some embodiments, the via portions of the first lower interconnection patterns 125, which are electrically connected to each other, may be horizontally shifted from each other, and the shifted via portions may be connected to each other by the head portions. However, the present inventive concept is not limited to this example. The first lower interconnection patterns 125 may include a conductive material. For example, in some embodiments, the first lower interconnection patterns 125 may be formed of or include at least one of copper (Cu), aluminum (Al), silver (Ag), tin (Sn), gold (Au), nickel (Ni), lead (Pb), and/or titanium (Ti).

The second lower interconnection patterns 126 may be interconnection patterns of the lower interconnection patterns 124, which are directly or electrically connected to the second vertical interconnection patterns 114. For example, in some embodiments, the second lower interconnection patterns 126 may be one or more heat-dissipation patterns that are used to transfer the heat, which is generated in the first or second semiconductor chip 200 or 300, to a region residing below the package substrate 100, and may also be one or more interconnection patterns, which are used to deliver a power signal or a ground signal to the first or second semiconductor chip 200 or 300. The via portion of the second lower interconnection pattern 126 may decrease in width as a distance to the core portion 110 decreases. For example, in some embodiments, the via portion of the second lower interconnection pattern 126 may have a tapered shape. As shown in FIGS. 1 and 2, in some embodiments, the second lower interconnection patterns 126, which are electrically connected to each other, may be vertically aligned, or overlapped, with each other. The via portions of the second lower interconnection patterns 126, which are electrically connected to each other, may be vertically overlapped with each other. However, the present inventive concept is not limited to this example.

The head and via portions of the second lower interconnection pattern 126 may be formed of different materials from each other. For convenience, as described herein, the head portion of the second lower interconnection pattern 126 will be referred to as a lower conductive pattern 127, and the via portion of the second lower interconnection pattern 126 will be referred to as a lower thermoelectric pattern 128.

The lower conductive pattern 127 may include the same material as the first lower interconnection patterns 125. The lower conductive pattern 127 may include a conductive material. For example, in some embodiments, the lower conductive pattern 127 may be formed of or include at least one of copper (Cu), aluminum (Al), silver (Ag), tin (Sn), gold (Au), nickel (Ni), lead (Pb), and/or titanium (Ti).

The lower thermoelectric pattern 128 may include the same material as the thermoelectric patterns 115 or the same conductive material as the thermoelectric patterns 115. The lower thermoelectric pattern 128 may be formed of or include an n-type semiconductor material or an n-type thermoelectric conversion pattern.

Depending on the material of the lower conductive pattern 127 and the material of the lower thermoelectric pattern 128, the second lower interconnection patterns 126, which are electrically connected to each other, may be provided to have a serially-connected structure, in which the lower conductive patterns 127 and the lower thermoelectric patterns 128 are alternately disposed. The heat-dissipation pattern (i.e., the second lower interconnection patterns 126), which is provided in the lower buildup portion 120 of the package substrate 100, may operate as a thermoelectric device and may be used to dissipate heat, which is transferred from the second vertical interconnection patterns 114, to a region residing below the lower buildup portion 120 (i.e., the package substrate 100).

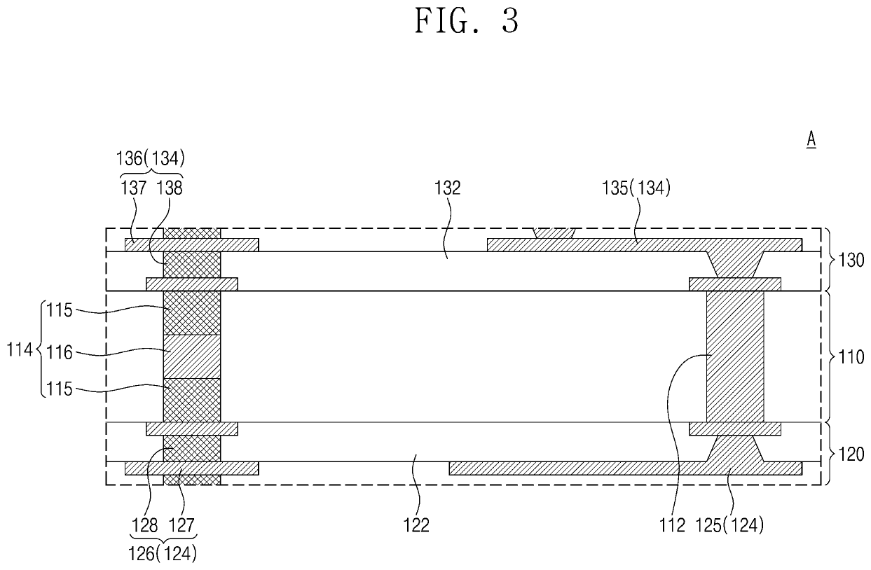

As shown in FIG. 2, according to some embodiments of the present inventive concept, the via portion of the second lower interconnection pattern 126 is illustrated to have the tapered shape, but the present inventive concept is not limited to this example. As shown in FIG. 3, in some embodiments, the via portion (i.e., the lower thermoelectric pattern 128) of the second lower interconnection pattern 126 may be provided to have a constant width. For example, in some embodiments, the lower thermoelectric pattern 128 may be a pillar-shaped pattern with a constant width. As an example, the lower thermoelectric patterns 128 may have a shape of the circular pillar.

The lower buildup portion 120 may further include lower substrate pads 101 and a lower substrate protection layer 104.

In some embodiments, the lower substrate pads 101 may be disposed on a bottom surface of the lowermost one of the first interconnection layers. In detail, the lower substrate pads 101 may be disposed on a bottom surface of the lowermost one of the lower insulating patterns 122, and a portion of each of the lower substrate pads 101 may be provided to penetrate the lowermost one of the lower insulating patterns 122 and may be coupled to the lower interconnection patterns 124. The lower substrate pads 101 may include first lower substrate pads 102, which are connected to the first lower interconnection patterns 125, and second lower substrate pads 103, which are connected to the second lower interconnection patterns 126. In other words, the first lower substrate pads 102 may be signal pads, which are configured to deliver operation signals to the package substrate 100 and the first and second semiconductor chips 200 and 300, and the second lower substrate pads 103 may be power pads, which are configured to supply a power signal or a ground signal to the package substrate 100 and the first and second semiconductor chips 200 and 300. The lower substrate pads 101 may be formed of or include at least one metallic material (e.g., copper (Cu)).

In some embodiments, a lower substrate protection layer 104 may be provided. The lower substrate protection layer 104 may cover the lower substrate pads 101, on the bottom surface of the lowermost one of the first substrate interconnection layers. In another embodiment, the lower substrate protection layer 104 may be provided to cover the bottom surface of the lowermost one of the first substrate interconnection layers and to expose the bottom surfaces of the lower substrate pads 101. The lower substrate protection layer 104 may be formed of or include at least one of insulating polymers or photoimageable polymers (e.g., PID).

In some embodiments, one or more outer terminals 105 may be provided on bottom surfaces of the lower substrate pads 101. For example, the outer terminals 105 may be provided to penetrate the lower substrate protection layer 104 and may be coupled to the lower substrate pads 101. In other words, the outer terminals 105, which are connected to the first lower substrate pads 102, may be signal terminals, which are configured to deliver operation signals to the package substrate 100 and the first and second semiconductor chips 200 and 300, and the outer terminals 105, which are connected to the second lower substrate pads 103, may be power terminals, which are configured to supply a power signal or a ground signal to the package substrate 100 and the first and second semiconductor chips 200 and 300. The outer terminals 105 may include solder balls or solder bumps. The semiconductor package may be classified into a ball grid array (BGA) package, a fine ball-grid array (FBGA) package, or a land grid array (LGA) package, depending on the kind and arrangement of the outer terminals 150.

In some embodiments, the upper buildup portion 130 may be disposed on the top surface of the core portion 110. The upper buildup portion 130 may cover the top surface of the core portion 110. The upper buildup portion 130 may include one or more second interconnection layers, which are sequentially stacked on the top surface of the core portion 110. Each of the second interconnection layers may include an upper insulating pattern 132 and upper interconnection patterns 134 in the upper insulating pattern 132. That is, the upper buildup portion 130 may include the upper insulating patterns 132, which are sequentially stacked, and the upper interconnection patterns 134, which are provided in the upper insulating patterns 132. The upper interconnection patterns 134 in one of the second interconnection layers may be electrically connected to the upper interconnection patterns 134 in another one of the second interconnection layers adjacent thereto. Hereinafter, the upper insulating pattern 132 and the upper interconnection patterns 134 will be described in more detail with reference to one of the second interconnection layers.

In some embodiments, the upper insulating pattern 132 may constitute at least a portion of an insulating portion of the package substrate 100. That is, the core portion 110, the lower insulating pattern 122 and the upper insulating pattern 132 may constitute an insulating portion of the package substrate 100. The upper insulating pattern 132 may be formed of or include at least one of prepreg, Ajinomoto build-up film (ABF), FR-4, and/or bismaleimide triazine (BT).

In some embodiments, the upper interconnection patterns 134 may be provided below the upper insulating pattern 132. The upper interconnection patterns 134 may be exposed to a bottom surface of the upper insulating pattern 132. A bottom surface of the upper interconnection pattern 134 may be coplanar with the bottom surface of the upper insulating pattern 132. The upper interconnection patterns 134 may not be exposed to a top surface of the upper insulating pattern 132. For example, in some embodiments, the upper interconnection patterns 134 may be disposed on the top surface of the core portion 110 or the top surface of another one of second interconnection layer, and the upper insulating pattern 132 may cover the upper interconnection patterns 134, on the top surface of the core portion 110 or the top surface of another one of second interconnection layer. The upper interconnection patterns 134 may extend horizontally in the upper insulating pattern 132. As described above, the upper interconnection patterns 134 may serve as pad or wire portions of the second interconnection layer.

Each of the upper interconnection patterns 134 may have a damascene structure. For example, in some embodiments, the upper interconnection pattern 134 may include a via portion that extends downward from a bottom surface thereof. The via portion may be used to vertically connect the upper interconnection patterns 134 of the second interconnection layers, which are adjacent to each other. For example, in some embodiments, the via portion may be extended from the bottom surface of the upper interconnection pattern 134 to penetrate the upper insulating pattern 132 of another one of the second interconnection layers thereunder and may be coupled to a top surface of the upper interconnection pattern 134 of the another one of the second interconnection layers. In other words, an upper portion of the upper interconnection pattern 134, which is placed in the upper insulating pattern 132, may be a head portion that is used as a horizontal line or a pad, and the via portion of the upper interconnection pattern 134 may be a tail portion. In some embodiments, the upper interconnection patterns 134 may have a shape of the letter ‘T’. The via portion of the upper interconnection pattern 134 may decrease in width as a distance to the core portion 110 decreases. In other words, the via portion of the upper interconnection pattern 134 may have a tapered shape.

The upper interconnection patterns 134 of the lowermost one of the second interconnection layers, which is in direct contact with the core portion 110, may not have the via portion. For example, in some embodiments, the upper interconnection pattern 134 of the lowermost one of the second interconnection layers may have only the head portion. In detail, a bottom surface of the lowermost one of the upper interconnection patterns 134 may be coplanar with a bottom surface of the lowermost one of the upper insulating patterns 132. The lowermost one of the upper interconnection patterns 134 may be connected to the top surface of the core portion 110 (e.g., the top surfaces of the first and second vertical interconnection patterns 112 and 114).

The upper interconnection patterns 134 may include first upper interconnection patterns 135 and second upper interconnection patterns 136.

In some embodiments, the first upper interconnection patterns 135 may be one or more interconnection patterns of the upper interconnection patterns 134, which are directly or electrically connected to the first vertical interconnection patterns 112. For example, in some embodiments, the first upper interconnection patterns 135 may be interconnection patterns, which are configured to deliver operation signals to the first or second semiconductor chip 200 or 300. The via portion of the first upper interconnection pattern 135 may decrease in width as a distance to the core portion 110 decreases. In other words, the via portion of the first upper interconnection pattern 135 may have a tapered shape. As shown in FIGS. 1 and 2, in some embodiments, the first upper interconnection patterns 135, which are electrically connected to each other, may not be vertically aligned to each other. As an example, in some embodiments, the via portions of the first upper interconnection patterns 135, which are electrically connected to each other, may be horizontally shifted from each other, and the shifted via portions may be connected to each other by the head portions. However, the present inventive concept is not limited to this example. The first upper interconnection patterns 135 may include a conductive material. For example, the first upper interconnection patterns 135 may be formed of or include at least one of copper (Cu), aluminum (Al), silver (Ag), tin (Sn), gold (Au), nickel (Ni), lead (Pb), and/or titanium (Ti).

In some embodiments, the second upper interconnection patterns 136 may be one or more interconnection patterns of the upper interconnection patterns 134, which are directly or electrically connected to the second vertical interconnection patterns 114. In other words, the second upper interconnection patterns 136 may be one or more heat-dissipation patterns that are configured to transfer the heat, which is generated in the first or second semiconductor chip 200 or 300, to a region residing below the package substrate 100, and may also be one or more interconnection patterns, which are configured to deliver a power signal or a ground signal to the first or second semiconductor chip 200 or 300. The via portion of the second upper interconnection pattern 136 may decrease in width as a distance to the core portion 110 decreases. For example, in some embodiments, the via portion of the second upper interconnection pattern 136 may have a tapered shape. As shown in FIGS. 1 and 2, in some embodiments, the second upper interconnection patterns 136, which are electrically connected to each other, may be vertically aligned, or overlapped, with each other. The via portions of the second upper interconnection patterns 136, which are electrically connected to each other, may be vertically overlapped with each other. However, the present inventive concept is not limited to this example.

The head and via portions of the second upper interconnection patterns 136 may be formed of different materials from each other. For convenience, as described herein, the head portion of the second upper interconnection pattern 136 will be referred to as an upper conductive pattern 137, and the via portion of the second upper interconnection pattern 136 will be referred to as an upper thermoelectric pattern 138.

The upper conductive pattern 137 may include the same material as the first upper interconnection patterns 135. The upper conductive pattern 137 may include a conductive material. For example, the upper conductive pattern 137 may be formed of or include at least one of copper (Cu), aluminum (Al), silver (Ag), tin (Sn), gold (Au), nickel (Ni), lead (Pb), and/or titanium (Ti).

The upper thermoelectric pattern 138 may include the same material as the thermoelectric patterns 115 or the same conductive material as the thermoelectric patterns 115. The upper thermoelectric pattern 138 may be formed of or include an n-type semiconductor material or an n-type thermoelectric conversion pattern.

Depending on the material of the upper conductive pattern 137 and the material of the upper thermoelectric pattern 138, the second upper interconnection patterns 136, which are electrically connected to each other, may be provided to have a serially-connected structure, in which the upper conductive patterns 137 and the upper thermoelectric patterns 138 are alternately disposed. The heat-dissipation pattern (i.e., the second upper interconnection patterns 136), which is provided in the upper buildup portion 130 of the package substrate 100, may operate as a thermoelectric device and may be used to dissipate heat, which is transferred from the first and second semiconductor chips 200 and 300, to the second vertical interconnection patterns 114.

According to some embodiments of the present inventive concept, the second lower interconnection patterns 126, the second vertical interconnection patterns 114, and the second upper interconnection patterns 136 may operate as a thermoelectric device, which is provided to vertically penetrate the package substrate 100 and includes the conductive patterns 116, 127, and 137 and the thermoelectric patterns 115, 128, and 138 that are alternately disposed. Thus, the second lower interconnection patterns 126, the second vertical interconnection patterns 114, and the second upper interconnection patterns 136 may occupy a small area, when viewed in a plan view, and thereby, it may be possible to reduce an area for the thermoelectric device and overall size of the semiconductor package.

In addition, the thermoelectric device, which is composed of the second lower interconnection patterns 126, the second vertical interconnection patterns 114, and the second upper interconnection patterns 136, may be provided to fully penetrate the package substrate 100 in a vertical direction. Thus, the heat, which is generated in the first and second semiconductor chips 200 and 300, may be easily dissipated to a region below the package substrate 100 via the package substrate 100. As a result, it may be possible to realize the semiconductor package with improved heat-dissipation efficiency.

As shown in FIG. 2, in some embodiments, the via portion of the second upper interconnection patterns 136 is illustrated to have a tapered shape, but the present inventive concept is not limited to this example. As shown in FIG. 3, in some embodiments, the via portion (i.e., the upper thermoelectric pattern 138) of the second upper interconnection pattern 136 may have a constant width. For example, in some embodiments, the upper thermoelectric pattern 138 may be a pillar-shaped pattern with a constant width. In another embodiment, the upper thermoelectric pattern 138 may have a shape of the circular pillar.

Referring back to FIGS. 1 and 2, in some embodiments, the upper interconnection patterns 134 provided in the uppermost second interconnection layer may be used as upper substrate pads, to which the first and second semiconductor chips 200 and 300 to be described below will be coupled. For example, in some embodiments, some of the upper interconnection patterns 134 in the uppermost second interconnection layer may be first upper substrate pads 106, which are coupled to the first semiconductor chip 200, and some of the upper interconnection patterns 134 in the uppermost second interconnection layer may be second upper substrate pads 107, which are coupled to the second semiconductor chip 300.

In some embodiments, the upper buildup portion 130 may further include an upper substrate protection layer 108. The upper substrate protection layer 108 may cover the uppermost second interconnection layer. The upper substrate protection layer 108 may cover the upper insulating pattern 132 and may enclose the upper substrate pads 106 and 107. The upper substrate pads 106 and 107 may be exposed to the outside of the upper substrate protection layer 108 near a top surface of the upper substrate protection layer 108. The upper substrate protection layer 108 may be formed of or include at least one of insulating polymers or photoimageable polymers. In some embodiments, the upper substrate protection layer 108 may not be provided.

In some embodiments, a first semiconductor chip 200 may be provided on the package substrate 100. The first semiconductor chip 200 may be mounted on a top surface of the package substrate 100. The first semiconductor chip 200 may be mounted on the package substrate 100 in a flip chip manner. In more detail, the first semiconductor chip 200 may have a front surface and a rear surface. As used herein, the term ‘front surface’ may be defined as an active surface of a semiconductor chip, on which an integrated device, interconnection lines, or pads of the semiconductor chip are formed, and the term ‘rear surface’ may be defined as a surface that is opposite to the front surface. In some embodiments, the first semiconductor chip 200 may be disposed to have the front surface facing the package substrate 100. In other words, the first semiconductor chip 200 may be disposed on the package substrate 100 in a face-down manner. In some embodiments, one or more first chip terminals 204 may be formed between first chip pads 202 of the first semiconductor chip 200 and the first upper substrate pads 106 of the package substrate 100 and may be coupled to the first chip pads 202 and the first upper substrate pads 106, respectively. The first chip terminals 204 may include, for example, solder balls. In some embodiments, some of the first chip terminals 204 may be coupled to the first upper substrate pads 106 connected to the first upper interconnection patterns 135, and others of the first chip terminals 204 may be coupled to the first upper substrate pads 106 connected to the second upper interconnection pattern 136. The first semiconductor chip 200 may be configured to send or receive operation signals through the first upper interconnection patterns 135 and the first upper substrate pads 106. The first semiconductor chip 200 may be configured to receive a power signal VCC through the second upper interconnection patterns 136 and the first upper substrate pads 106. In more detail, the power signal VCC may be input through the outer terminals 105, which reside on the second lower substrate pads 103, and may be transmitted to the first semiconductor chip 200, along the current flow CF, through the second lower substrate pads 103, the second lower interconnection patterns 126, the second vertical interconnection patterns 114, the second upper interconnection patterns 136, and the first upper substrate pads 106. Heat, which is generated during the operation of the first semiconductor chip 200, may be transferred and dissipated to a region, which resides below the package substrate 100, through the first chip terminals 204, the second upper interconnection patterns 136, the second vertical interconnection patterns 114, and the second lower interconnection patterns 126 and may be exhausted to the outside of the package substrate 100.

According to some embodiments of the present inventive concept, the internal lines (e.g., the second upper interconnection patterns 136, the second vertical interconnection patterns 114, and the second lower interconnection patterns 126), which are provided in the package substrate 100 and are configured to supply electrical power to the first semiconductor chip 200, may be used as a thermoelectric device for heat dissipation. Thus, it may be possible to perform the heat-dissipation operation using the electric power, which is supplied to the first semiconductor chip 200, and no additional interconnection lines may be required to operate the thermoelectric device. Thus, it may be possible to reduce the overall size of the semiconductor package.

In addition, both of the operations of the first semiconductor chip 200 and the thermoelectric device may be executed using the same electric power. The operation of the thermoelectric device may be actively executed, depending on the operation of the first semiconductor chip 200. That is, it may be possible to realize a semiconductor package having improved electrical and heat-dissipation characteristics.

Furthermore, since the second upper interconnection patterns 136, the second vertical interconnection patterns 114, and the second lower interconnection patterns 126, which are used as the thermoelectric device, reside directly below the first semiconductor chip 200, the heat, which is generated in the first semiconductor chip 200, may be easily transferred and dissipated to a region below the package substrate 100. As a result, it may be possible to realize a semiconductor package having improved heat-dissipation efficiency.

In some embodiments, a second semiconductor chip 300 may be provided on the package substrate 100. The second semiconductor chip 300 may be mounted on the top surface of the package substrate 100. The second semiconductor chip 300 may be mounted on the package substrate 100 in a wire bonding manner. In more detail, the second semiconductor chip 300 may have a front surface and a rear surface. The second semiconductor chip 300 may be placed such that the rear surface thereof faces the package substrate 100. That is, the second semiconductor chip 300 may be disposed on the package substrate 100 in a face-up manner. In some embodiments, one or more second chip terminals 304 may be formed between second chip pads 302 of the second semiconductor chip 300 and the second upper substrate pads 107 of the package substrate 100 and may be coupled to the second chip pads 302 and the second upper substrate pads 107, respectively. The second chip terminals 304 may include, for example, bonding wires. In some embodiments, some of the second chip terminals 304 may be coupled to the second upper substrate pads 107 connected to the first upper interconnection patterns 135, and others of the second chip terminals 304 may be coupled to the second upper substrate pads 107 connected to the second upper interconnection pattern 136. The second semiconductor chip 300 may be configured to send or receive operation signals through the first upper interconnection patterns 135 and the second upper substrate pads 107. The second semiconductor chip 300 may be configured to receive a power signal through the second upper interconnection patterns 136 and the second upper substrate pads 107. Heat, which is generated during the operation of the second semiconductor chip 300, may be transferred and dissipated to a region, which resides below the package substrate 100, through the second chip terminals 304, the second upper interconnection patterns 136, the second vertical interconnection patterns 114, and the second lower interconnection patterns 126 and may be exhausted to the outside of the package substrate 100.

FIG. 1 illustrates an example according to some embodiments of the present inventive concept, in which the first semiconductor chip 200 is mounted on the package substrate 100 in a flip chip manner and the second semiconductor chip 300 is mounted on the package substrate 100 in a wire bonding manner. However, this is an example of various ways of mounting semiconductor chips on the package substrate 100, and the present inventive concept is not limited to this example. For example, in some embodiments, one or more semiconductor chips 200, 300 may be provided on the package substrate 100 by a flip chip method, a wire bonding method, or other various mounting method.

Hereinafter, an element previously described with reference to FIGS. 1 to 3 may be identified by the same reference number without repeating an overlapping description thereof, for convenience in description. That is, technical features, which are different from those in the embodiments of FIGS. 1 to 3, will be mainly described below.

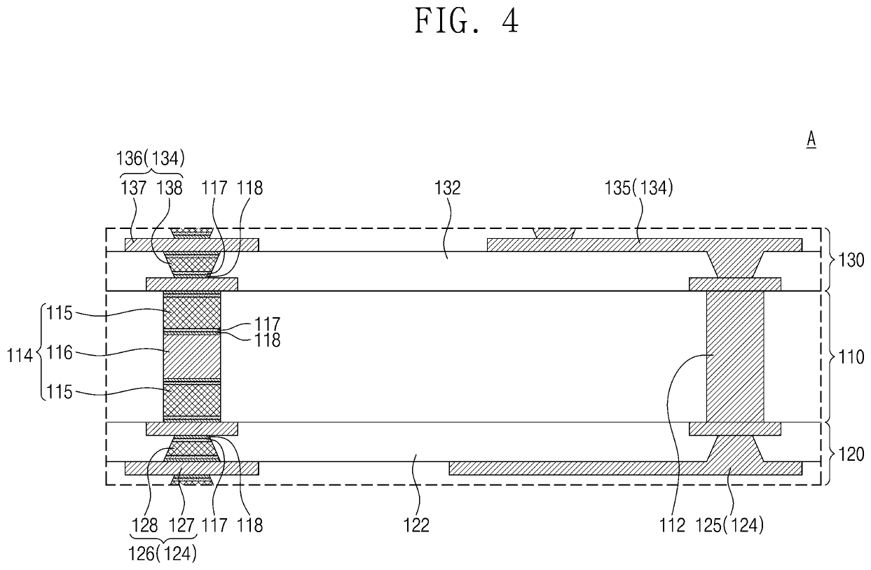

FIG. 4 illustrates an enlarged view of a portion ‘A’ of the semiconductor package of FIG. 1 according to some embodiments of the present inventive concept.

Referring to FIGS. 1 and 4, in some embodiments, the second vertical interconnection patterns 114 may further include contact patterns 117 and 118. In more detail, the contact patterns 117 and 118 may include one or more first contact patterns 117, which are in contact with the thermoelectric patterns 115, and one or more second contact patterns 118, which are in contact with the conductive pattern 116. One of the first contact patterns 117 and one of the second contact patterns 118 may be provided between the thermoelectric pattern 115 and the conductive pattern 116, which are paired to each other and are placed adjacent to each other.

In the case where the conductive pattern 116 is in direct contact with the thermoelectric pattern 115, the conductive pattern 116 and the thermoelectric pattern 115 may form the Schottky junction. Since the first and second contact patterns 117 and 118 are interposed between the conductive pattern 116 and the thermoelectric patterns 115, the first and second contact patterns 117 and 118 may form an ohmic junction in conjunction with the conductive pattern 116 and the thermoelectric patterns 115. Thus, an electric resistance between the conductive pattern 116 and the thermoelectric patterns 115 may be lowered, and the electrical characteristics of the semiconductor package may be improved. The first contact pattern 117 may be formed of or include nickel (Ni). The second contact pattern 118 may be formed of or include gold (Au).

In some embodiments, the first and second contact patterns 117 and 118 may be provided in or between the second upper interconnection patterns 136, the second vertical interconnection patterns 114, and the second lower interconnection patterns 126 constituting the heat-dissipation pattern. For example, in some embodiments, the first and second contact patterns 117 and 118 may be provided between the lower conductive pattern 127 and the lower thermoelectric pattern 128 of the lower buildup portion 120, between the lower conductive pattern 127 of the lower buildup portion 120 and the thermoelectric pattern 115 of the core portion 110, between the upper conductive pattern 137 and the upper thermoelectric pattern 138 of the upper buildup portion 130, and between the upper conductive pattern 137 of the upper buildup portion 130 and the thermoelectric pattern 115 of the core portion 110. Here, the first contact patterns 117 may be in contact with the thermoelectric patterns 128, 115, and 138 of the lower buildup portion 120, the core portion 110, and the upper buildup portion 130, and the second contact patterns 118 may be in contact with the conductive patterns 127, 116, and 137 of the lower buildup portion 120, the core portion 110, and the upper buildup portion 130. In some embodiments, the first and second contact patterns 117 and 118 may be provided in at least one, but not all, of regions between the lower conductive pattern 127 and the lower thermoelectric pattern 128, between the lower conductive pattern 127 and the thermoelectric pattern 115, between the upper conductive pattern 137 and the upper thermoelectric pattern 138, and between the upper conductive pattern 137 and the thermoelectric pattern 115.

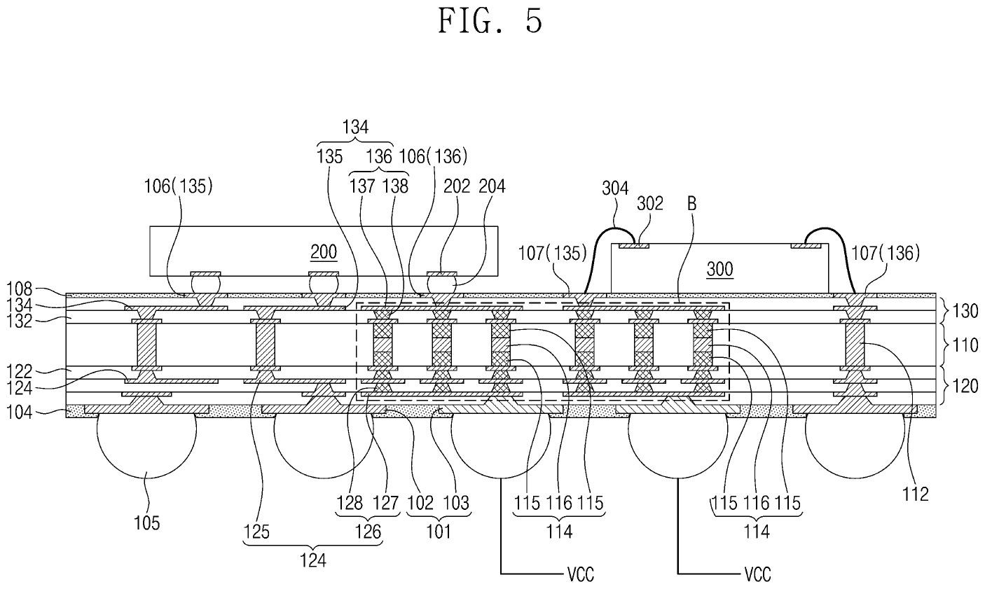

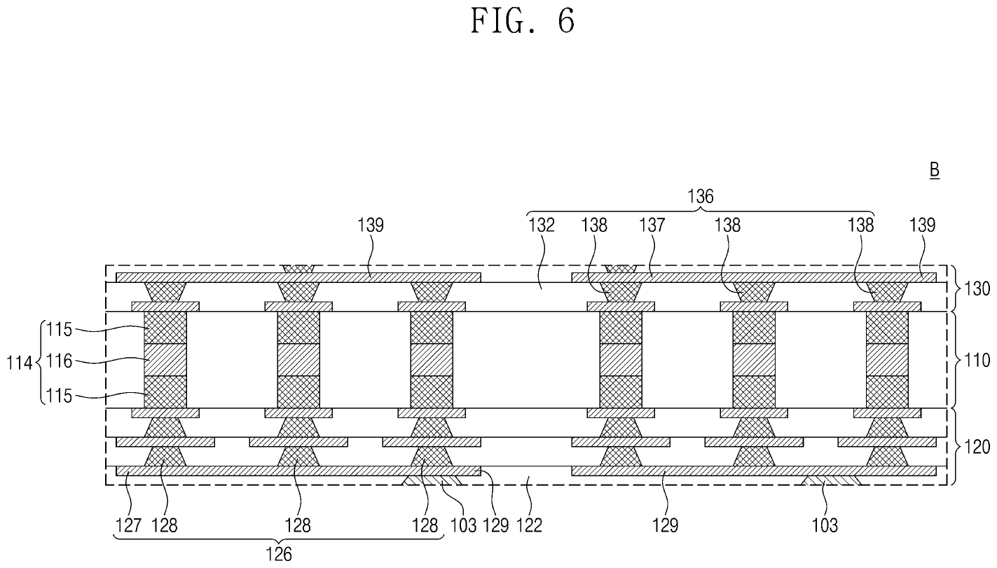

FIG. 5 is a sectional view illustrating a semiconductor package according to some embodiments of the present inventive concept. FIG. 6 is an enlarged sectional view of the semiconductor package illustrating a portion ‘B’ of FIG. 5.

FIGS. 1 to 4 illustrate an example according to some embodiments of the present inventive concept, in which one second vertical interconnection pattern 114 is provided below the first semiconductor chip 200 and one second vertical interconnection pattern 114 is provided below the second semiconductor chip 300, but the present inventive concept is not limited to this example.

Referring to FIGS. 5 and 6, in some embodiments, a plurality of second vertical interconnection patterns 114 may be provided below the first semiconductor chip 200, and a plurality of second vertical interconnection patterns 114 may be provided below the second semiconductor chip 300. The following description will be given based on the second vertical interconnection patterns 114 placed below the first semiconductor chip 200.

In some embodiments, the second vertical interconnection patterns 114 below the first semiconductor chip 200 may be horizontally spaced apart from each other. The second vertical interconnection patterns 114 may be connected in parallel. For example, in some embodiments, lower ends of the second vertical interconnection patterns 114 may be connected to one of second lower interconnection patterns 129 of the lower buildup portion 120. Alternatively, the second lower interconnection patterns 126, which are directly connected to the second vertical interconnection patterns 114, may be connected to one of the second lower interconnection patterns 129 in another first interconnection layer. As an example, in some embodiments, the second lower conductive pattern 129, which is the lowermost one of the conductive patterns 139, 116, and 127 constituting each of the heat-dissipation patterns, may extend horizontally, and in some embodiments, it may be electrically connected to the second lower interconnection patterns 126 and the second vertical interconnection patterns 114 or may be electrically connected to the second lower substrate pad 103 and the outer terminal 105 applied with the electric power. Upper ends of the second vertical interconnection patterns 114 may be connected to one of the second upper interconnection pattern 139 in the upper buildup portions 130. Alternatively, in some embodiments, the second upper interconnection patterns 136, which are directly connected to the second vertical interconnection patterns 114, may be connected to one of the second upper interconnection patterns 139 in another second interconnection layer. The second vertical interconnection patterns 114 may be used as a conduction path of the power signal VCC that is transmitted to the first semiconductor chip 200.

In some embodiments, the second vertical interconnection patterns 114 below the second semiconductor chip 300 may be horizontally spaced apart from each other. The second vertical interconnection patterns 114 may be connected in parallel. For example, in some embodiments, lower ends of the second vertical interconnection patterns 114 may be connected to one of the second lower interconnection patterns 129 of the lower buildup portion 120. Alternatively, in some embodiments, the second lower interconnection patterns 126, which are directly connected to the second vertical interconnection patterns 114, may be connected to one of the second lower interconnection patterns 129 in another first interconnection layer. Upper ends of the second vertical interconnection patterns 114 may be connected to one of the second upper interconnection pattern 139 in the upper buildup portions 130. Alternatively, in some embodiments, the second upper interconnection patterns 136, which are directly connected to the second vertical interconnection patterns 114, may be connected to one of the second upper interconnection patterns 139 in another second interconnection layer. The second vertical interconnection patterns 114 may be used as a conduction path of the power signal VCC that is transmitted to the second semiconductor chip 300.

According to some embodiments of the present inventive concept, the second vertical interconnection patterns 114 may be connected to a single electric power in parallel. That is, the second vertical interconnection patterns 114 may share the single electric power, and in some embodiments, to supply an electric power to each of the second vertical interconnection patterns 114, it may be unnecessary to form additional interconnection lines. Thus, it may be possible to improve the electrical characteristics of the semiconductor package as well as reduce the overall size of the semiconductor package. In addition, since the heat-dissipation patterns (i.e., the lower interconnection patterns 126, the second vertical interconnection patterns 114, and the upper interconnection patterns 136) vertically penetrating the package substrate 100 are provided in several regions where heat dissipation is required, it may be possible to achieve heat dissipation over a larger area. As a result, it may be possible to realize the semiconductor package having improved heat-dissipation efficiency.

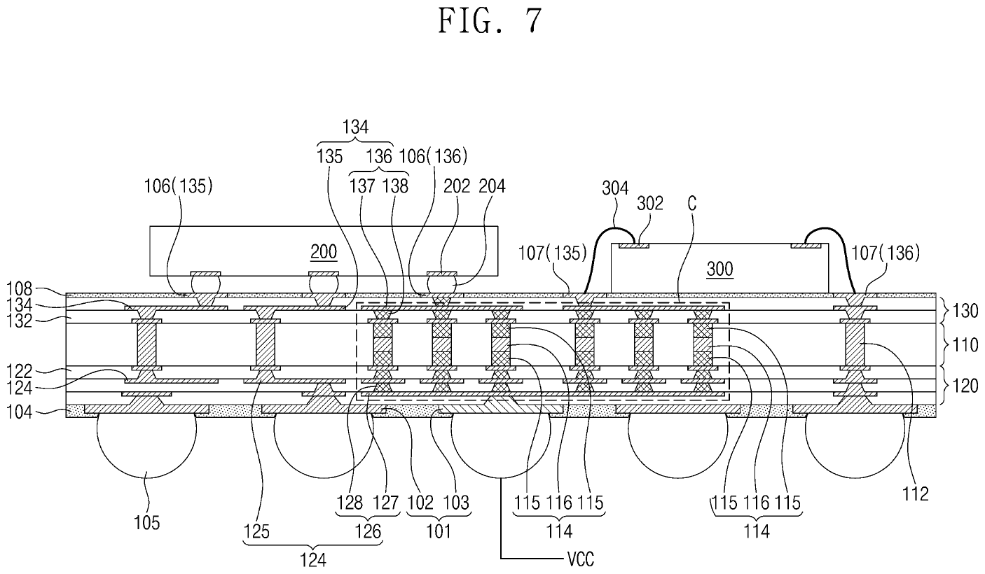

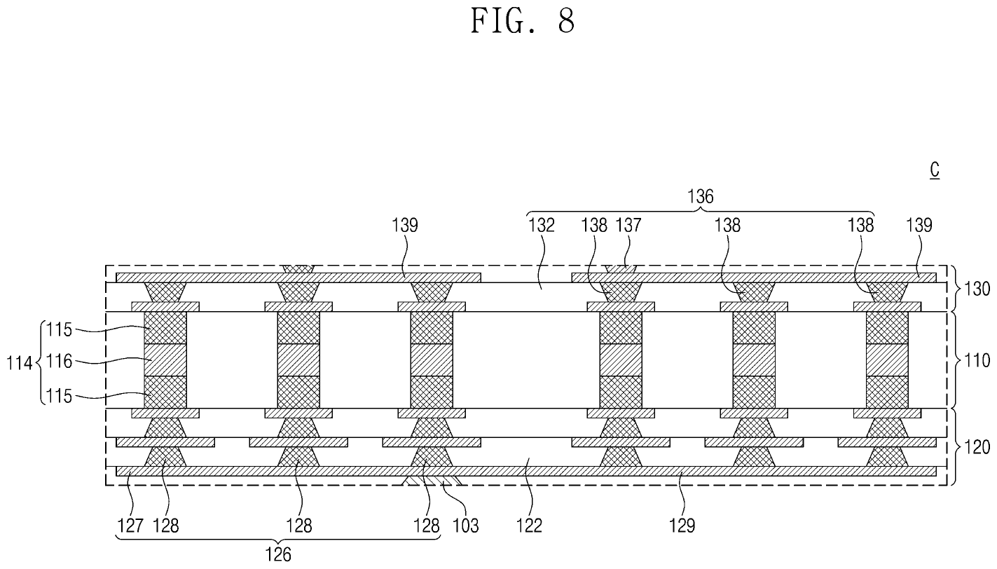

FIG. 7 is a sectional view illustrating a semiconductor package according to some embodiments of the present inventive concept. FIG. 8 is an enlarged sectional view of the semiconductor package illustrating a portion ‘C’ of FIG. 7.

FIGS. 5 and 6 illustrate an example according to embodiments of the present inventive concept, in which the second vertical interconnection patterns 114 connected to the first and second semiconductor chips 200 and 300, respectively, are configured to form different circuits from each other or are disconnected from each other, but the present inventive concept is not limited to this example.

Referring to FIGS. 7 and 8, in some embodiments, the second vertical interconnection patterns 114, which reside below and are connected to the first semiconductor chip 200, and the second vertical interconnection patterns 114, which reside below and are connected to the second semiconductor chip 300, may be connected in parallel. For example, in some embodiments, lower ends of the second vertical interconnection patterns 114 may be connected to one of second lower interconnection patterns 129 of the lower buildup portion 120. Alternatively, in some embodiments, the second lower interconnection patterns 126, which are directly connected to the second vertical interconnection patterns 114, may be connected to one of the second lower interconnection patterns 129 in another first interconnection layer. Upper ends of the second vertical interconnection patterns 114 may be connected to one of the second upper interconnection pattern 139 in the upper buildup portions 130. Alternatively, in some embodiments, the second upper interconnection patterns 136, which are directly connected to the second vertical interconnection patterns 114, may be connected to one of the second upper interconnection patterns 139 in another second interconnection layer. Some of the second vertical interconnection patterns 114 may be configured as a part of a conduction path of the power signal VCC that is transmitted to the first semiconductor chip 200, and others of the second vertical interconnection patterns 114 may be configured as a part of a conduction path of the power signal VCC that is transmitted to the second semiconductor chip 300. That is, the first and second semiconductor chips 200 and 300 may share the same power.

According to some embodiments of the present inventive concept, by exploiting the shape of the second lower interconnection patterns 126 of the lower buildup portion 120, it may be possible to provide the second vertical interconnection patterns 114 at various regions within the package substrate 100, regardless of the positions of the second lower substrate pads 103 connected to the electric power. In addition, since each of the heat-dissipation patterns (i.e., the lower interconnection patterns 126, the second vertical interconnection patterns 114, and the upper interconnection patterns 136) have a small area in a plan view, the thermoelectric devices may be placed in the package substrate 100 with reduced restrictions on their positions.

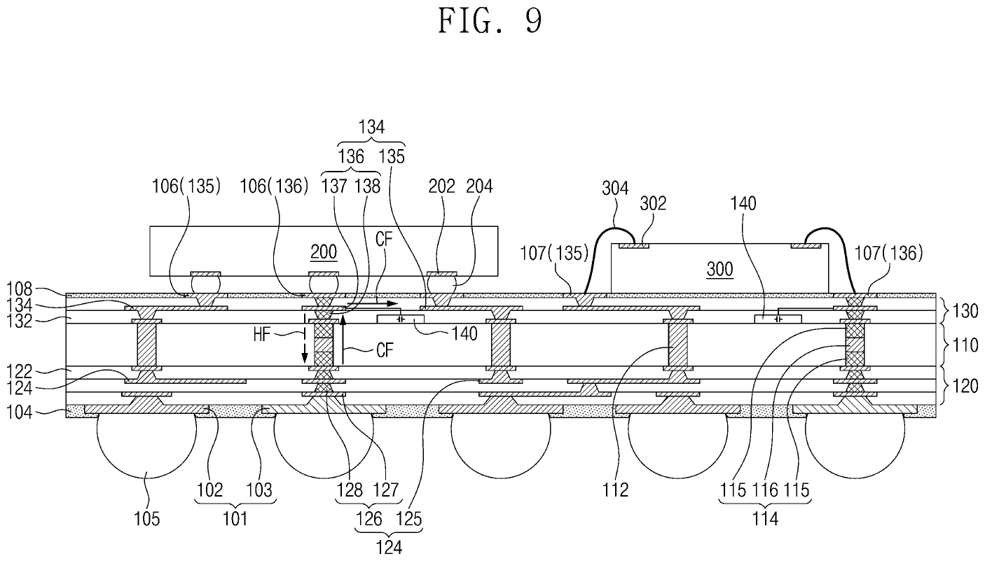

FIG. 9 is a sectional view illustrating a semiconductor package according to some embodiments of the present inventive concept.

Referring to FIG. 9, in some embodiments, the package substrate 100 of the semiconductor package may further include a capacitor device 140 therein. The capacitor device 140 may be a capacitor pattern provided in the upper buildup portion 130. For example, in some embodiments, the capacitor device 140 may include two electrodes, which are parts of the upper interconnection patterns 134, and a dielectric layer, which is provided between the two electrodes. Alternatively, in some embodiments, the capacitor device 140 may be a device that is separately inserted in the upper buildup portion 130. The capacitor device 140 may be electrically connected to the upper conductive pattern 137 of the second upper interconnection pattern 136 of the upper buildup portion 130. For example, in some embodiments, the capacitor device 140 may be connected to at least one of the second vertical interconnection patterns 114. In some embodiments, a plurality of capacitor devices 140 may be provided in the semiconductor package.

The capacitor device 140 may store an electric power using the heat, which is generated in the first or second semiconductor chip 200 or 300. In detail, the heat, which is generated in the first or second semiconductor chip 200 or 300, may be transferred through the second upper interconnection patterns 136, the second vertical interconnection patterns 114, and the second lower interconnection patterns 126, which have high thermal conductivity, as depicted as the heat flow HF in FIG. 9. Here, an electromotive force may be produced by the heat flow HF in the second upper interconnection patterns 136, the second vertical interconnection patterns 114, and the second lower interconnection patterns 126 constituting the thermoelectric device. Since the thermoelectric patterns 128, 115, and 138 include the n-type semiconductor material, the current flow CF may be produced in an opposite direction of the heat flow HF. The current flow CF may conduct to the capacitor device 140 along the second vertical interconnection patterns 114 and the second upper interconnection patterns 136. Thus, the electric power may be stored in the capacitor device 140.

According to some embodiments of the present inventive concept, the heat, which is generated in the first and second semiconductor chips 200 and 300, may be converted to electricity and stored in the capacitor device 140. In an embodiment, the electric power, which is stored in the capacitor device 140, may be used in the semiconductor package. Thus, a semiconductor package with improved electrical characteristics may be provided.

FIG. 10 is a sectional view illustrating a semiconductor package according to some embodiments of the present inventive concept.

FIG. 9 illustrates an example according to some embodiments of the present inventive concept, in which the capacitor device 140 is provided in the package substrate 100, but the present inventive concept is not limited to this example.

Referring to FIG. 10, in some embodiments, the capacitor device 140, which is provided as a separated device, may be mounted on the package substrate 100. For example, in some embodiments, the capacitor device 140 may include a pad 144, which is provided on a bottom surface thereof, and may be mounted on the package substrate 100 using a connection terminal 146, which is provided between the pad 144 and one of the first upper substrate pads 106 of the package substrate 100. In some embodiments, the connection terminal 146 may include a solder ball, as shown in FIG. 10, or may include a bonding wire, unlike the illustrated structure.

The heat, which is generated in the first or second semiconductor chip 200 or 300, may be transferred through the second upper interconnection patterns 136, the second vertical interconnection patterns 114, and the second lower interconnection patterns 126, which have high thermal conductivity, as depicted as the heat flow HF in FIG. 10. Here, an electromotive force may be produced by the heat flow HF in the second upper interconnection patterns 136, the second vertical interconnection patterns 114, and the second lower interconnection patterns 126 constituting the thermoelectric device. The current flow CF may be produced in the opposite direction of the heat flow HF. The current may conduct along the second vertical interconnection patterns 114 and the second upper interconnection patterns 136 and may be supplied to the capacitor device 140. Thus, the electric power may be stored in the capacitor device 140.

FIG. 11 is a sectional view illustrating a semiconductor module according to some embodiments of the present inventive concept.

Referring to FIG. 11, in some embodiments, the semiconductor package may be a semiconductor module. The semiconductor module may be, for example, a memory module including an interposer 100, a graphic processing unit 400 and a chip stack 500 mounted on the interposer 100, and an outer mold layer 600 covering the graphic processing unit 400 and the chip stack 500. The semiconductor module may further include a module substrate, which is placed below the interposer 100, and the interposer 100 may be mounted on a module substrate.

Although not shown, the module substrate may be provided. The module substrate may include a printed circuit board (PCB), in which signal patterns are provided on a top surface thereof.

In some embodiments, one or more module terminals may be disposed below the module substrate. The module terminals may include solder balls or solder bumps, and the semiconductor module may be classified into a ball grid array (BGA) module, a fine ball-grid array (FBGA) module, or a land grid array (LGA) module, depending on the kind and arrangement of the module terminals. In some embodiments, the module terminals may not be provided.

In some embodiments, the interposer 100 may be provided on the module substrate. The interposer 100 may have the same or similar structure as the package substrate 100 described with reference to FIGS. 1 to 10. For example, in some embodiments, the interposer 100 may include the core portion 110, the lower buildup portion 120, and the upper buildup portion 130 and may further include the thermoelectric patterns 115 and the conductive patterns 116, which are provided to vertically penetrate the core portion 110 and are connected in series.

The interposer 100 may serve as a redistribution structure for the graphic processing unit 400 and the chip stack 500. The interposer 100 may be mounted on the module substrate in a flip chip manner. For example, in some embodiments, the interposer 100 may be mounted on the module substrate using the outer terminals 105, which are provided on the lower substrate pads 101. The outer terminals 105 may include solder balls or solder bumps.

In some embodiments, the graphic processing unit 400 may be disposed on the interposer 100. The graphic processing unit 400 may include a logic circuit. In other words, the graphic processing unit 400 may be a logic chip. The graphic processing unit 400 may include a first circuit layer 402 that is provided on a bottom surface thereof. The first circuit layer 402 may be electrically connected to the logic circuit. First bumps 404 may be provided on a bottom surface of the graphic processing unit 400 (i.e., a bottom surface of the first circuit layer 402). The first bumps 404 may be placed on the upper buildup portion 130. The graphic processing unit 400 may be coupled to the first upper substrate pads 106 of the upper buildup portion 130 through the first bumps 404. A first under fill layer 406 may be provided between the interposer 100 and the graphic processing unit 400. The first under fill layer 406 may be provided to fill a space between the interposer 100 and the graphic processing unit 400 and to enclose the first bumps 404.

In some embodiments, the chip stack 500 may be disposed on the interposer 100. The chip stack 500 may be spaced apart from the graphic processing unit 400. A thickness of the graphic processing unit 400 may be larger than a thickness of each of the semiconductor chips 510 and 520 of the chip stack 500. A top surface of the chip stack 500 may be located at a level that is equal to or higher than a top surface of the graphic processing unit 400.

The chip stack 500 may include a base substrate, the third semiconductor chips 520 stacked on the base substrate, and a mold layer 530 enclosing the third semiconductor chips 520. Hereinafter, the structure of the chip stack 500 will be described in more detail below.

The base substrate may be a base semiconductor chip 510. For example, in some embodiments, the base substrate may be a wafer-level semiconductor substrate that is formed of a semiconductor material (e.g., silicon (Si)). Hereinafter, the base semiconductor chip 510 may be the same element as the base substrate, and the base semiconductor chip and the base substrate may be identified using the same reference number.

In some embodiments, the base semiconductor chip 510 may include a base circuit layer 512 and base penetration electrodes 514. The base circuit layer 512 may be provided on a bottom surface of the base semiconductor chip 510. The base circuit layer 512 may include an integrated circuit. For example, in some embodiments, the base circuit layer 512 may be a memory circuit. That is, the base semiconductor chip 510 may be a memory chip (e.g., a DRAM, SRAM, MRAM or FLASH memory chip). Alternatively, in some embodiments, the base semiconductor chip 510 may be a logic chip. The base penetration electrodes 514 may penetrate the base semiconductor chip 510 in a direction perpendicular to a top surface of the interposer 100. The base penetration electrodes 514 and the base circuit layer 512 may be electrically connected to each other. The bottom surface of the base semiconductor chip 510 may be an active surface. In some embodiments, the base substrate may be an interconnection substrate, which does not include the base semiconductor chip 510.

In some embodiments, a third semiconductor chip 520 may be mounted on the base semiconductor chip 510. In other words, the third semiconductor chip 520 and the base semiconductor chip 510 may form a chip-on-wafer (COW) structure. A width of the third semiconductor chip 520 may be smaller than a width of the base semiconductor chip 510.

In some embodiments, the third semiconductor chip 520 may include a second circuit layer 522 and chip penetration electrodes 524. The second circuit layer 522 may include a memory circuit. That is, the third semiconductor chip 520 may be a memory chip (e.g., a DRAM, SRAM, MRAM or FLASH memory chip). The second circuit layer 522 may include the same circuit as the base circuit layer 512, but the present inventive concept is not limited to this example. The chip penetration electrodes 524 may penetrate the third semiconductor chip 520 in a direction that is perpendicular to the top surface of the interposer 100. The chip penetration electrodes 524 and the second circuit layer 522 may be electrically connected to each other. A bottom surface of the third semiconductor chip 520 may be an active surface.

The third semiconductor chip 520 may be bonded to the base semiconductor chip 510. For example, in some embodiments, a pad of the second circuit layer 522 of the third semiconductor chip 520 may be in contact with a top surface of the base penetration electrode 514, which is exposed to a top surface of the base semiconductor chip 510. Alternatively, in some embodiments, the third semiconductor chip 520 may be mounted on the top surface of the base penetration electrodes 514 using terminals that are provided on the pads of the second circuit layer 522.

In some embodiments, a plurality of third semiconductor chips 520 may be provided. For example, in some embodiments, the third semiconductor chips 520 may be stacked on the base semiconductor chip 510. In some embodiments, 8 to 32 third semiconductor chips 520 may be stacked. Here, the topmost one of the third semiconductor chips 520 may not include the chip penetration electrodes 524. Furthermore, a thickness of the topmost one of the third semiconductor chips 520 may be larger than a thickness of each of the third semiconductor chips 520 thereunder.

The third semiconductor chips 520, which are adjacent to each other, may be bonded to each other. For example, in some embodiments, pads of the second circuit layer 522 of each of the third semiconductor chips 520 may be in contact with top surfaces of the chip penetration electrodes 524, which are exposed to the outside of the third semiconductor chip 520 thereunder. Alternatively, in some embodiments, the third semiconductor chips 520 may be mounted on the top surfaces of the chip penetration electrodes 524 using terminals that are provided on the pads of the second circuit layer 522.

In some embodiments, the mold layer 530 may be disposed on the top surface of the base semiconductor chip 510. The mold layer 530 may cover the base semiconductor chip 510 and may enclose the third semiconductor chips 520. A top surface of the mold layer 530 may be coplanar with a top surface of the uppermost one of the third semiconductor chips 520, and the uppermost one of the third semiconductor chips 520 may be exposed to the outside of the mold layer 530. The mold layer 530 may include an insulating polymer material (e.g., an epoxy molding compound (EMC)).

The chip stack 500 may be provided to have the structure described herein.

In some embodiments, second bumps 504 may be provided on a bottom surface of the chip stack 500 (i.e., a bottom surface of the base circuit layer 512). The chip stack 500 may be coupled to the second upper substrate pads 107 of the upper buildup portion 130 through the second bumps 504. A second under fill layer 506 may be provided between the interposer 100 and the chip stack 500. The second under fill layer 506 may be provided to fill a space between the interposer 100 and the chip stack 500 and to enclose the second bumps 504.

In some embodiments, an outer mold layer 600 may be provided on the interposer 100. The outer mold layer 600 may cover the top surface of the interposer 100. The outer mold layer 600 may enclose the graphic processing unit 400 and the chip stack 500. A top surface of the outer mold layer 600 may be located at the same level as the top surface of the chip stack 500. The outer mold layer 600 may include an insulating material. For example, in some embodiments, the outer mold layer 600 may be formed of or include an epoxy molding compound (EMC).

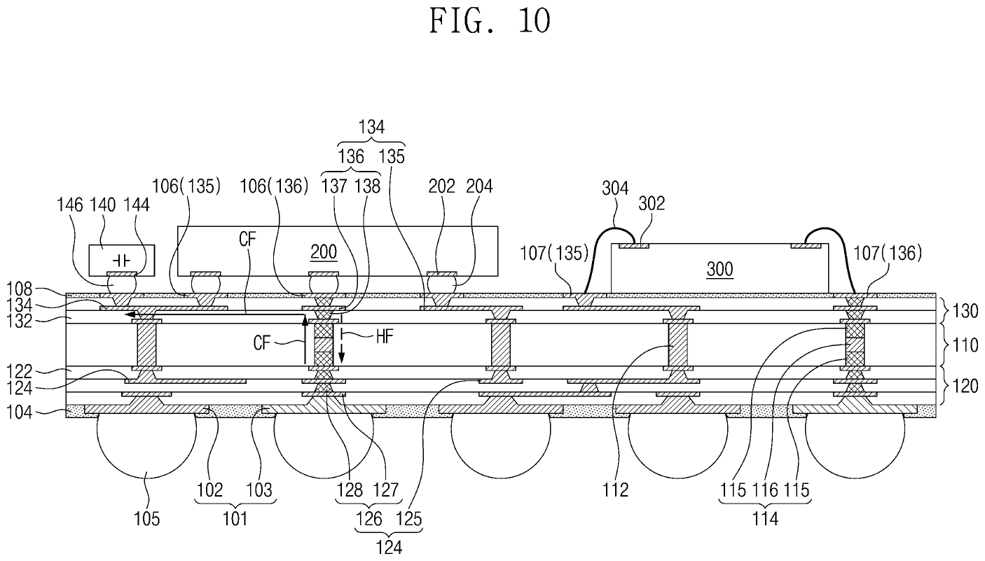

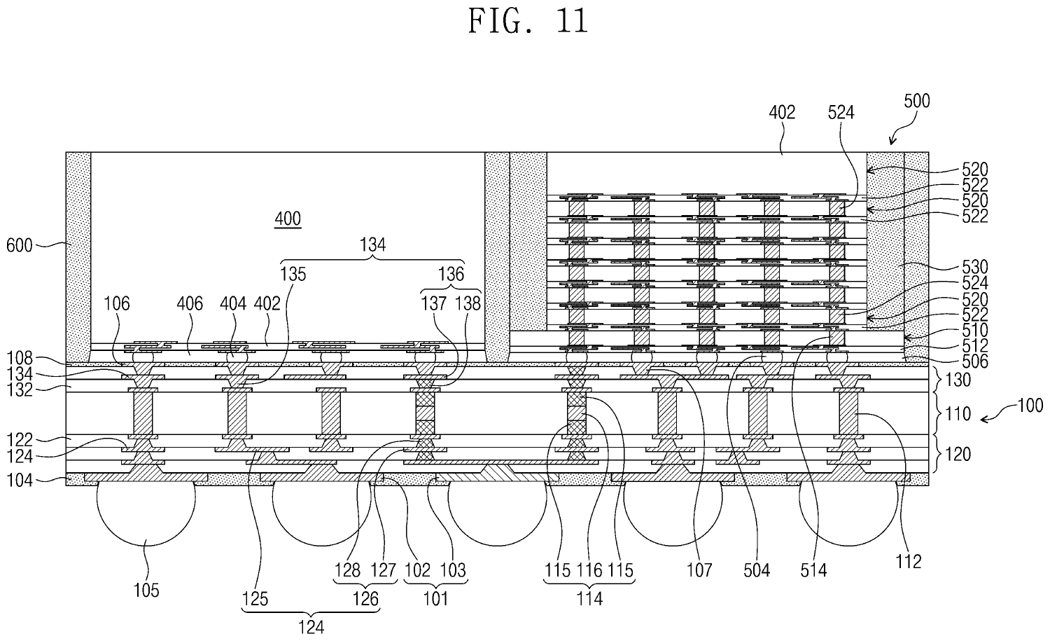

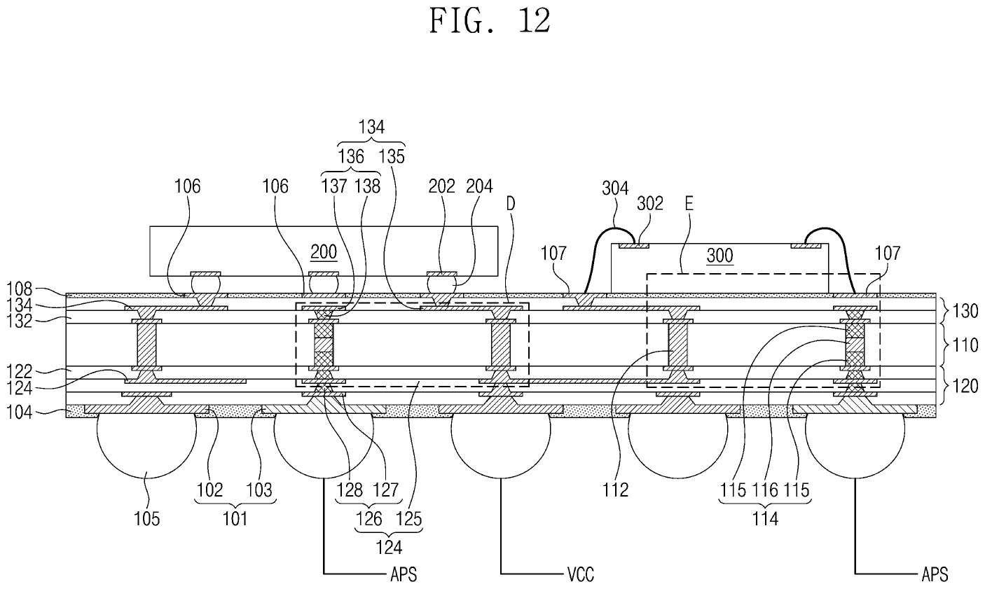

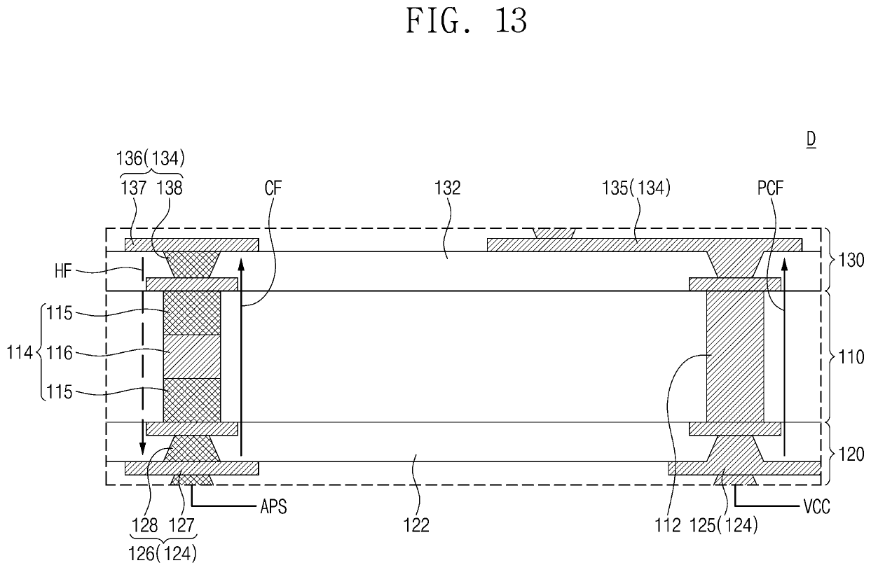

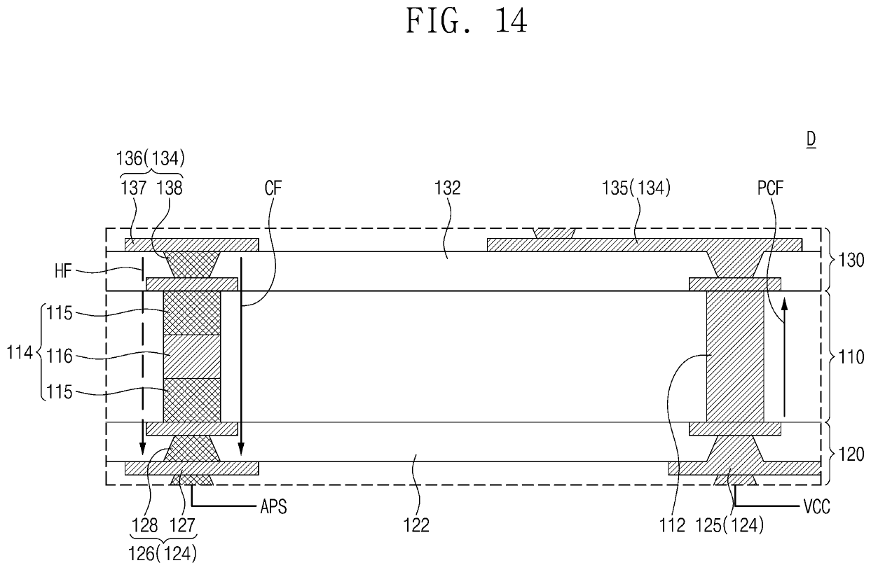

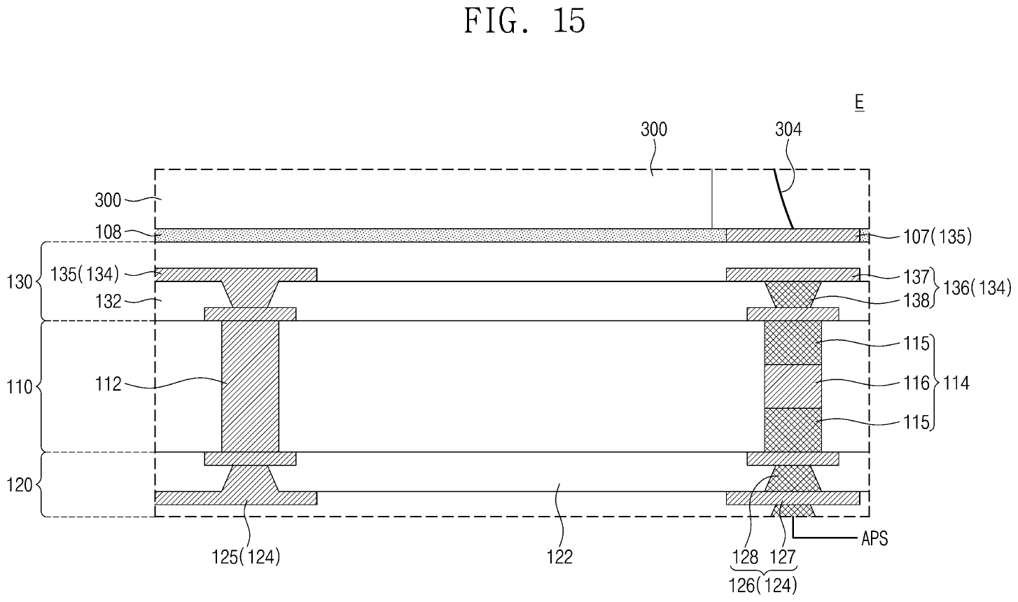

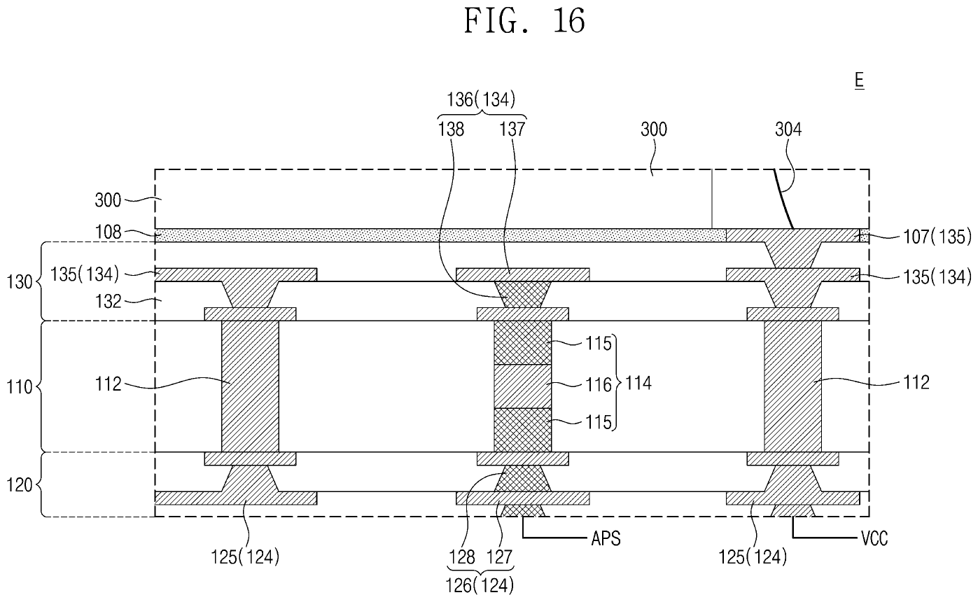

FIG. 12 is a sectional view illustrating a semiconductor package according to some embodiments of the present inventive concept. FIGS. 13 and 14 are enlarged sectional views of the semiconductor package illustrating a portion ‘D’ of FIG. 12. FIGS. 15 and 16 are enlarged sectional views of the semiconductor package illustrating a portion ‘E’ of FIG. 12.

Referring to FIGS. 12 to 14, in some embodiments, the second vertical interconnection patterns 114 may be electrically disconnected from the first and second semiconductor chips 200 and 300. For example, in some embodiments, the second vertical interconnection patterns 114 and the second upper interconnection patterns 136 connected thereto may be electrically disconnected from the first upper substrate pads 106 and the second upper substrate pads 107, which are coupled to the first and second semiconductor chips 200 and 300.

The power signal VCC, configured to operate the first and second semiconductor chips 200 and 300, may be transmitted to the first and second semiconductor chips 200 and 300 through some of the first vertical interconnection patterns 112. For example, in some embodiments, and as depicted by the arrow in FIG. 13, a current flow PCF delivering an electric power may be supplied to the first or second semiconductor chip 200 or 300 through the first lower interconnection patterns 125, the first vertical interconnection patterns 112, and the first upper interconnection patterns 135.

The second vertical interconnection patterns 114 and the second lower interconnection patterns 126 connected thereto may be connected to the second lower substrate pads 103. In some embodiments, an additional power signal APS may be transmitted to the second lower substrate pads 103. The additional power signal APS may be a power signal, which is configured to operate the thermoelectric device that is composed of the second lower interconnection patterns 126, the second vertical interconnection patterns 114, and the second upper interconnection patterns 136. For example, in some embodiments, the thermoelectric device may form a separate circuit in the package substrate 100. In some embodiments, the additional power signal APS may have a positive voltage or a negative voltage, because the additional power signal APS is only used to operate the thermoelectric device.

As an example, in some embodiments, the thermoelectric patterns 128, 115, and 138 may be formed of or include an n-type semiconductor material or an n-type thermoelectric conversion pattern. In some embodiments, for example, as shown in FIG. 13, the current flow CF of the additional power signal APS may conduct from the lower buildup portion 120 toward the upper buildup portion 130, and the heat flow HF may conduct from the upper buildup portion 130 toward the lower buildup portion 120.

Alternatively, in some embodiments, the thermoelectric patterns 128, 115, and 138 may include a p-type semiconductor material or a p-type thermoelectric conversion pattern. In some embodiments, for example, as shown in FIG. 14, the current flow CF of the additional power signal APS may conduct from the upper buildup portion 130 toward the lower buildup portion 120, and the heat flow HF may conduct from the upper buildup portion 130 toward the lower buildup portion 120.

Referring to FIG. 15, in some embodiments, the second vertical interconnection patterns 114 may be provided below the upper substrate pads 106 and 107. The heat, which is generated in the first and second semiconductor chips 200 and 300, may be transferred to the second upper interconnection patterns 136, the second vertical interconnection patterns 114, and the second lower interconnection patterns 126 through the upper substrate pads 106 and 107 and the upper insulating pattern 132 of the package substrate 100.

Alternatively, as shown in FIG. 16, in some embodiments, the second vertical interconnection patterns 114 may reside below the first and second semiconductor chips 200 and 300. It may be unnecessary to connect the second upper interconnection patterns 136, the second vertical interconnection patterns 114, and the second lower interconnection patterns 126 to the upper substrate pads 106 and 107, and thus, the second upper interconnection patterns 136, the second vertical interconnection patterns 114, and the second lower interconnection patterns 126 may not be disposed below the upper substrate pads 106 and 107. In the case where the second semiconductor chip 300 is mounted in the wire bonding manner, the second upper interconnection patterns 136, the second vertical interconnection patterns 114, and the second lower interconnection patterns 126 may be easily disposed below the second semiconductor chip 300.

According to some embodiments of the present inventive concept, the thermoelectric device, which is composed of the second upper interconnection patterns 136, the second vertical interconnection patterns 114, and the second lower interconnection patterns 126, may be electrically disconnected from interconnection patterns in the first and second semiconductor chips 200 and 300. In the package substrate 100, the thermoelectric device may form a circuit that is independent of the first and second semiconductor chips 200 and 300. Thus, the position of the thermoelectric device may be determined independently of the positions of the upper substrate pads 106 and 107 that are used for mounting the first and second semiconductor chips 200 and 300. That is, the thermoelectric device may be placed with less restriction. In particular, it may be easy to place the thermoelectric device in regions below the first and second semiconductor chips 200 and 300, where most of the heat sources are located, and thus, the semiconductor package may have an improved heat-dissipation property.

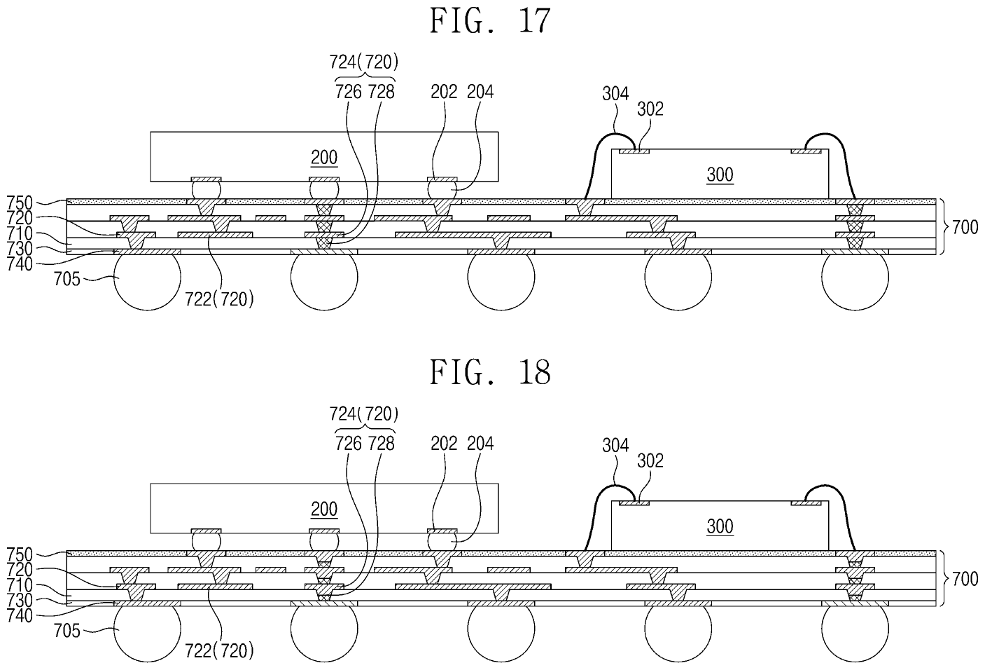

FIGS. 17 to 20 are sectional views, each of which illustrates a semiconductor package according to some embodiments of the present inventive concept.

Referring to FIG. 17, in some embodiments, a package substrate 700 may be provided. Unlike the package substrate 100 of FIG. 1, the package substrate 700 may be a redistribution substrate. For example, in some embodiments, the package substrate 700 may include one or more substrate interconnection layers that are stacked. Each of the substrate interconnection layers may include a substrate insulating pattern 710 and a substrate interconnection pattern 720 in the substrate insulating pattern 710. The substrate interconnection pattern 720 in one of the substrate interconnection layers may be electrically connected to the substrate interconnection pattern 720 in another one of the substrate interconnection layers.

The substrate insulating pattern 710 may constitute an insulating portion of the package substrate 700. The substrate insulating pattern 710 may be formed of or include at least one of photoimageable dielectric (PID) materials (e.g., photoimageable polyimide (PI), polybenzoxazole (PBO), phenol-based polymers, and/or benzocyclobutene-based polymers). Alternatively, in some embodiments, the substrate insulating pattern 710 may be formed of or include at least one insulating material (e.g., silicon oxide (SiO), silicon nitride (SiN), silicon oxynitride (SiON), or insulating polymers).

In some embodiments, the substrate interconnection pattern 720 may be provided on the substrate insulating pattern 710. The substrate interconnection pattern 720 may extend horizontally, on the top surface of the substrate insulating pattern 710. The substrate interconnection pattern 720 on the substrate insulating pattern 710 may be covered with another substrate insulating pattern 710 thereon. The substrate interconnection pattern 720, which is provided in the uppermost one of the substrate interconnection layers, may be used as a substrate pad. The substrate interconnection pattern 720 may include a metallic material (e.g., copper (Cu)). The substrate interconnection pattern 720 may have a damascene structure. For example, in some embodiments, the substrate interconnection pattern 720 may include a via portion, which is used to vertically connect the substrate interconnection patterns 720, which are provided in two adjacent substrate interconnection layers. For example, in some embodiments, the via portion may extend from the bottom surface of the substrate interconnection pattern 720 to penetrate the substrate insulating pattern 710 and may be coupled to a top surface of another substrate interconnection pattern 720 thereunder. For example, in some embodiments, an upper portion of the substrate interconnection pattern 720, which is placed on the substrate insulating pattern 710, may be a head portion that is used as a horizontal wire or a pad, and the via of the substrate interconnection pattern 720 may be a tail portion. In some embodiments, the substrate interconnection pattern 720 may have a shape of the letter ‘T’. The substrate interconnection pattern 720 may include first substrate interconnection patterns 722 and second substrate interconnection patterns 724.

The first substrate interconnection patterns 722 may be one or more interconnection patterns, which are configured to deliver an operation signal to the first or second semiconductor chip 200 or 300. The first lower interconnection patterns 125 may be formed of or include at least one conductive material (e.g., copper (Cu), aluminum (Al), silver (Ag), tin (Sn), gold (Au), nickel (Ni), lead (Pb), and/or titanium (Ti)).

For example, in some embodiments, the second substrate interconnection patterns 724 may be heat-dissipation patterns that are used to transfer the heat, which is generated in the first or second semiconductor chip 200 or 300, to a region residing below the package substrate 100, and may also be one or more interconnection patterns, which are configured to deliver a power signal or a ground signal to the first or second semiconductor chip 200 or 300. The second substrate interconnection patterns 724, which are electrically connected to each other, may be vertically aligned, or overlapped, with each other. The head and via portions of the second substrate interconnection patterns 724 may be formed of different materials from each other. For convenience, as described herein, the head portion of the second substrate interconnection pattern 724 will be referred to as a redistribution conductive pattern 726, and the via portion of the second substrate interconnection pattern 724 will be referred to as a redistribution thermoelectric pattern 728. The redistribution conductive pattern 726 may include the same material as the first substrate interconnection patterns 722. The redistribution conductive pattern 726 may be formed of or include at least one conductive material (e.g., copper (Cu), aluminum (Al), silver (Ag), tin (Sn), gold (Au), nickel (Ni), lead (Pb), and/or titanium (Ti)). The redistribution thermoelectric pattern 728 may be formed of or include an n-type semiconductor material or an n-type thermoelectric conversion pattern.

Depending on the material of the redistribution conductive pattern 726 and the material of the redistribution thermoelectric pattern 728, the second substrate interconnection patterns 724, which are electrically connected to each other, may be provided to have a serially-connected structure, in which the redistribution conductive pattern 726 and the redistribution thermoelectric pattern 728 are alternately disposed. In some embodiments, the second substrate interconnection patterns 724 may configured to operate as a thermoelectric device and may be used to dissipate heat, which is transferred from the first and second semiconductor chips 200 and 300, to a region residing below the package substrate 700.

In FIG. 17, according to some embodiments, the head portion of the second substrate interconnection patterns 724 is illustrated as the redistribution conductive pattern 726, and the via portion of the second substrate interconnection patterns 724 is illustrated as the redistribution thermoelectric pattern 728. That is, an interface between the redistribution conductive pattern 726 and the redistribution thermoelectric pattern 728 may be identical to a boundary between the head and via portions of the second substrate interconnection patterns 724. However, the present inventive concept is not limited to this example. As shown in FIG. 18, in some embodiments, the interface between the redistribution conductive pattern 726 and the redistribution thermoelectric pattern 728 may be located within the via portion of the second substrate interconnection patterns 724. The following description will be given based on the embodiment of FIG. 17.

In some embodiments, one or more outer pads 740 may be provided on a bottom surface of the lowermost one of the substrate interconnection layers. The outer pads 740 may be electrically connected to the substrate interconnection pattern 720. The outer pads 740 may be used as pads, to which outer terminals 705 are coupled.

In some embodiments, a substrate protection layer 730 may be provided. The substrate protection layer 730 may be formed to cover the bottom surface of the lowermost one of the substrate interconnection layers and expose the outer pads 740. The substrate protection layer 730 may be formed of or include at least one insulating polymer or photoimageable polymers (e.g., PID). The outer terminals 705 may be provided on bottom surfaces of the exposed outer pads 740. The outer terminals 705 may include solder balls or solder bumps, and the semiconductor package may include solder balls or solder bumps, and the semiconductor package may be classified into a ball grid array (BGA) package, a fine ball-grid array (FBGA) package, or a land grid array (LGA) package, depending on the kind and arrangement of the outer terminals 705.

In some embodiments, a solder resist pattern 750 may be provided. The solder resist pattern 750 may cover a top surface of the uppermost one of the substrate interconnection layers and enclose the substrate pads (i.e., the substrate interconnection patterns 720 in the uppermost one of the substrate interconnection layers). The solder resist pattern 750 may not cover the substrate pads. The solder resist pattern 750 may be formed of or include a solder resist material.

The first and second semiconductor chips 200 and 300 may be mounted on the package substrate 100. The first and second semiconductor chips 200 and 300 may be the same or similar as those in the embodiments shown in FIGS. 1 to 16, in terms of their structures, mounting methods, and positions of thermoelectric patterns.

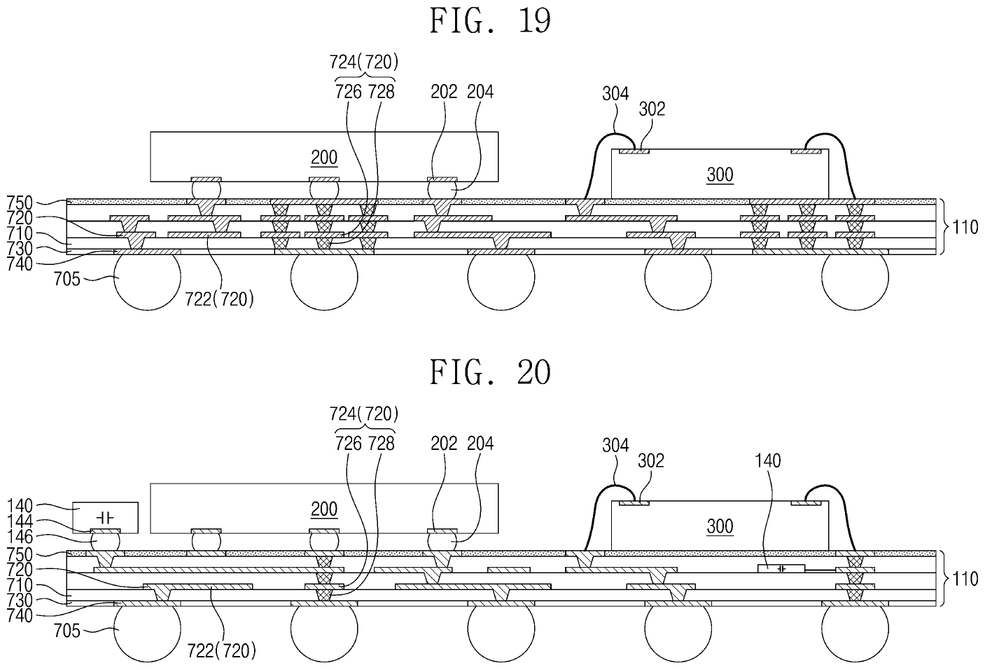

In some embodiments, the second substrate interconnection patterns 724 connected in series may be provided to form a plurality of thermoelectric devices, for example, as shown in FIG. 19. A plurality of thermoelectric devices may be provided below the first semiconductor chip 200, and a plurality of thermoelectric devices may be provided below the second semiconductor chip 300, similar to the embodiments shown in FIGS. 5 to 8. The thermoelectric devices may be connected in parallel.

In some embodiments, the semiconductor package may further include the capacitor device 140, for example, as shown in FIG. 20. The capacitor device 140 may be a capacitor pattern, which is provided in the package substrate 100, or may be mounted on the package substrate 100 as a separate device, similar to the embodiments shown in FIGS. 9 and 10.

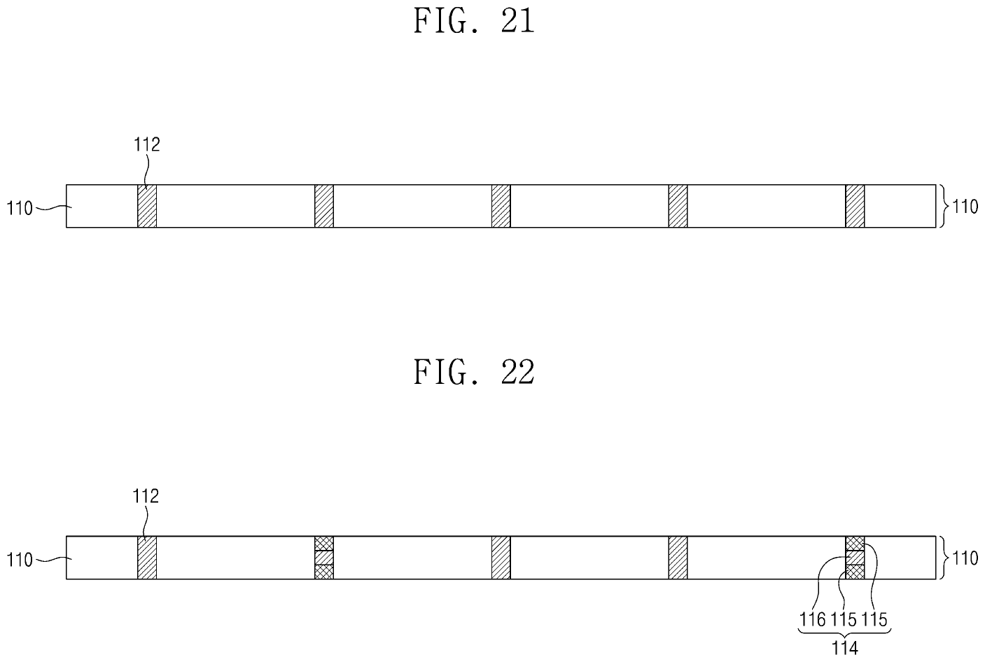

FIGS. 21 to 26 are sectional views illustrating a method of fabricating a semiconductor package, according to some embodiments of the present inventive concept.

Referring to FIG. 21, in some embodiments, the core portion 110 may be provided. The first vertical interconnection patterns 112 may be formed in the core portion 110. For example, in some embodiments, the formation of the first vertical interconnection patterns 112 may include forming holes to penetrate the core portion 110 and filling the holes with a conductive material.

Referring to FIG. 22, in some embodiments, an etch-back process may be performed on some of the first vertical interconnection patterns 112. The conductive pattern 116, which is placed at an intermediate level of the hole, may be formed by the etch-back process. The conductive pattern 116 may be formed to have a top surface, which is recessed downward from the top surface of the core portion 110, and a bottom surface, which is recessed upward from the bottom surface of the core portion 110.

Thereafter, the thermoelectric patterns 115 may be formed by filling remaining spaces of the holes with a thermoelectric material. The thermoelectric material may include an n-type semiconductor material or an n-type thermoelectric conversion pattern. The thermoelectric patterns 115 and the conductive pattern 116, which are provided to fill each hole, may constitute the second vertical interconnection pattern 114 vertically penetrating the core portion 110.

The first vertical interconnection patterns 112 and the second vertical interconnection patterns 114 may be formed in the core portion 110, as described above.

Referring to FIG. 23, in some embodiments, a conductive layer may be formed on the top surface of the core portion 110. The upper interconnection patterns 134 may be formed by patterning the conductive layer. One or more of the upper interconnection patterns 134 connected to the first vertical interconnection patterns 112 may correspond to the first upper interconnection patterns 135. In addition, one or more of the upper interconnection patterns 134 connected to the second vertical interconnection patterns 114 may correspond to the upper conductive patterns 137. The first upper interconnection patterns 135 and upper conductive patterns 137 may be formed of or include at least one of copper (Cu), aluminum (Al), silver (Ag), tin (Sn), gold (Au), nickel (Ni), lead (Pb), and/or titanium (Ti).

The upper insulating pattern 132 may be formed by coating or depositing an insulating material on the top surface of the core portion 110 to cover the first upper interconnection patterns 135 and the upper conductive patterns 137. Thereafter, the upper insulating pattern 132 may be patterned to form holes exposing the upper conductive patterns 137, and the upper thermoelectric patterns 138 may be formed by filling the holes with a thermoelectric material. The upper conductive pattern 137 and the upper thermoelectric pattern 138, which are connected to each other, may constitute the second upper interconnection pattern 136.

Referring to FIG. 24, in some embodiments, the upper insulating pattern 132 may be patterned to form holes exposing the first upper interconnection patterns 135, a conductive layer may be formed to cover the upper insulating pattern 132 and fill the holes, and then, the conductive layer may be patterned to form the upper interconnection patterns 134. The upper interconnection patterns 134 may include additional first upper interconnection patterns 135, which are connected to the first upper interconnection patterns 135, and additional upper conductive patterns 137, which are connected to the second upper interconnection pattern 136.

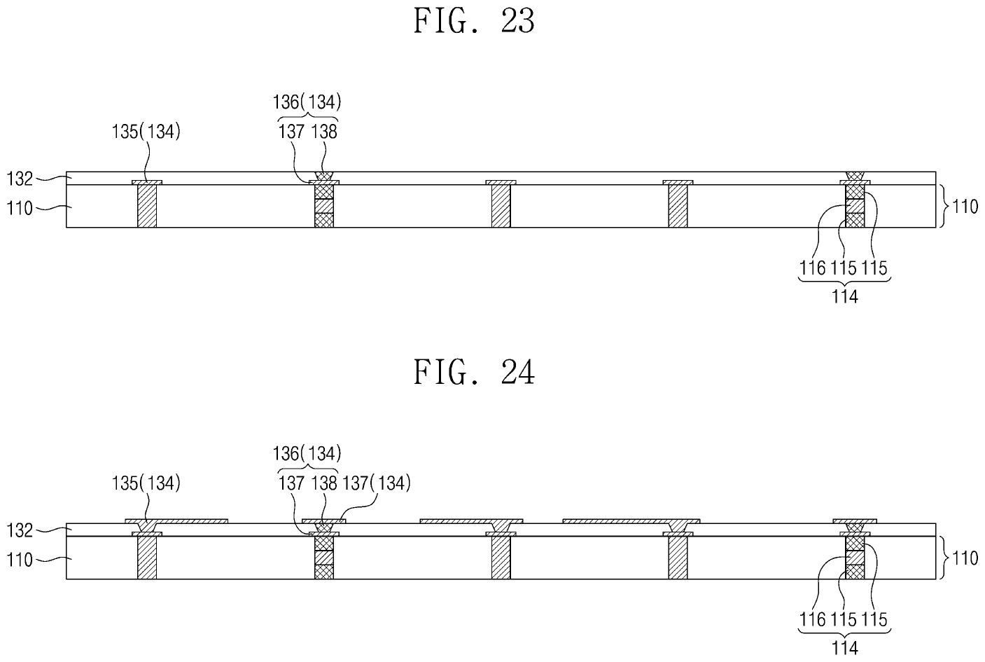

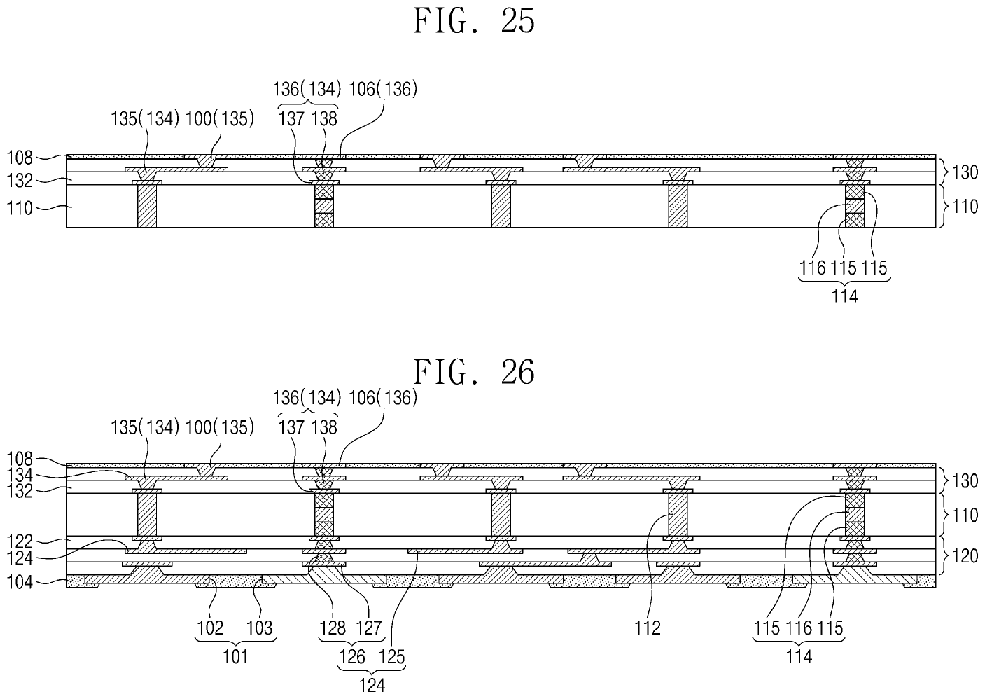

Referring to FIG. 25, in some embodiments, the process of forming the upper insulating pattern 132 and the upper interconnection patterns 134, as described herein, may be repeated. The upper insulating pattern 132 and the upper interconnection patterns 134 may constitute the upper buildup portion 130 described with reference to FIG. 1.

In some embodiments, the upper substrate protection layer 108 may be formed to cover the upper insulating patterns 132 and expose the uppermost ones of the upper interconnection patterns 134.

Referring to FIG. 26, in some embodiments, the lower buildup portion 120 may be formed on the bottom surface of the core portion 110. The lower buildup portion 120 may be formed by substantially the same or similar process as that for the upper buildup portion 130. For example, in some embodiments, the lower interconnection patterns 124 may be formed by forming a conductive layer on the bottom surface of the core portion 110 and patterning the conductive layer. The lower interconnection patterns 124 may include the first lower interconnection patterns 125, which are connected to the first vertical interconnection patterns 112, and the lower conductive patterns 127, which are connected to the second vertical interconnection patterns 114. The lower insulating pattern 122 may be formed on the top surface of the core portion 110 to cover the first lower interconnection patterns 125 and the lower conductive patterns 127 and may be patterned to form holes exposing the lower conductive patterns 127, and then, the lower thermoelectric patterns 128 may be formed by filling the holes with a thermoelectric material. The lower insulating pattern 122 may be patterned to form holes exposing the first lower interconnection patterns 125, a conductive layer may be formed to cover the lower insulating pattern 122 and fill the holes, and then, the lower interconnection patterns 124 may be formed by patterning the conductive layer. In some embodiments, the process of forming the lower insulating pattern 122 and the lower interconnection patterns 124 may be repeated. The lower insulating pattern 122 and the lower interconnection patterns 124 may constitute the lower buildup portion 120, as described herein with reference to FIG. 1.

The lower substrate protection layer 104 may be formed to cover the lower insulating patterns 122 and expose the uppermost ones of the lower interconnection patterns 124, and then, the lower substrate pads 101, which are connected to the lower interconnection patterns 124, may be formed to penetrate the lower substrate protection layer 104.

Referring back to FIG. 1, in some embodiments, the first and second semiconductor chips 200 and 300 may be mounted on the package substrate 100. The outer terminals 105 may be provided on the lower substrate pads 101.

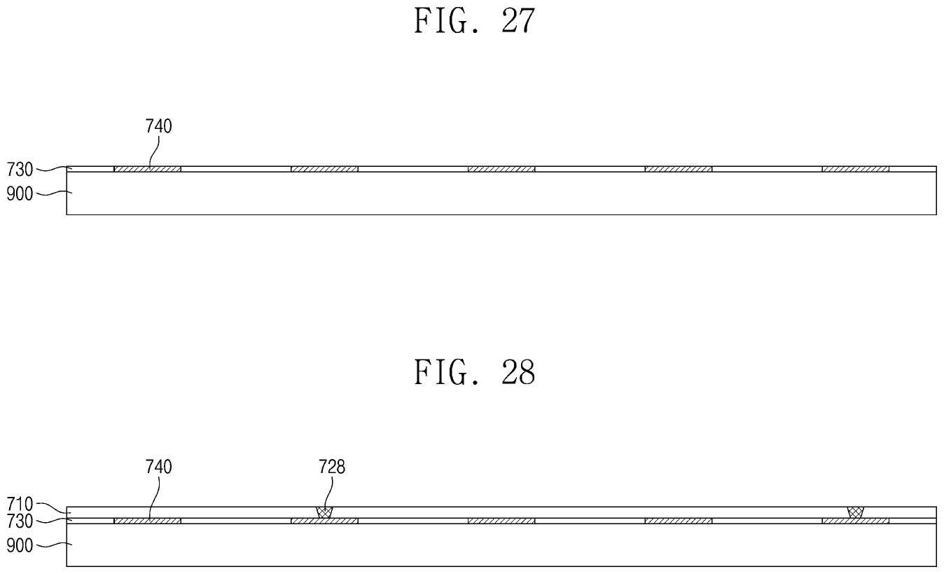

FIGS. 27 to 30 are sectional views illustrating a method of fabricating a semiconductor package according to some embodiments of the present inventive concept.

Referring to FIG. 27, in some embodiments, a carrier substrate 900 may be provided. The carrier substrate 900 may be an insulating substrate, which is formed of or includes glass or polymer, or a conductive substrate, which is formed of or includes a metallic material. Although not shown, an adhesive member (e.g., an adhesive tape) may be provided on a top surface of the carrier substrate 900.

The substrate protection layer 730 may be formed by depositing a photoimageable insulating layer on the carrier substrate 900. An exposure process may be performed on the substrate protection layer 730, and then, the substrate protection layer 730 may be patterned to form penetration holes. The outer pads 740 may be formed by filling the penetration holes of the substrate protection layer 730 with a conductive material.

Referring to FIG. 28, in some embodiments, the substrate insulating pattern 710 may be formed by depositing an insulating material on the substrate protection layer 730.

First penetration holes, which expose some of the outer pads 740, may be formed by patterning the substrate insulating pattern 710. The redistribution thermoelectric patterns 728 may be formed by filling the first penetration holes with a thermoelectric material. The thermoelectric material may include an n-type semiconductor material or an n-type thermoelectric conversion pattern.

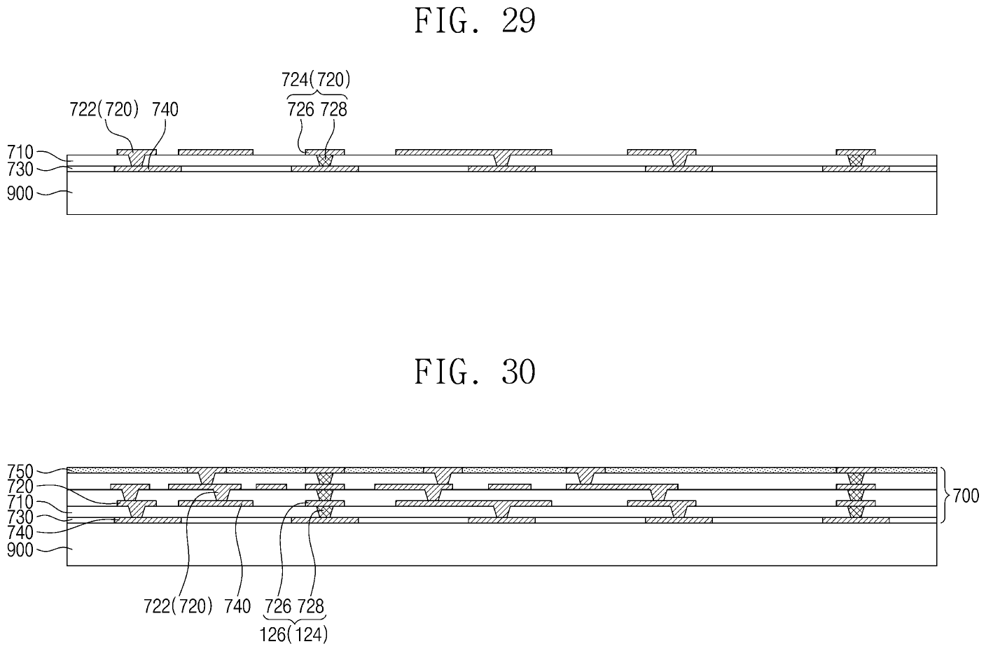

Referring to FIG. 29, in some embodiments, the substrate insulating pattern 710 may be patterned to form second penetration holes exposing remaining ones of the outer pads 740. A conductive layer may be formed to cover the substrate insulating pattern 710 and the redistribution thermoelectric patterns 728 and fill the second penetration holes, and then, may be patterned to form the substrate interconnection pattern 720. The substrate interconnection pattern 720 may include the first substrate interconnection patterns 722, which are coupled to the outer pads 740 through the second penetration holes, and the second substrate interconnection patterns 724, which are connected to the redistribution thermoelectric patterns 728.

Referring to FIG. 30, in some embodiments, the process of forming the substrate insulating pattern 710, the redistribution thermoelectric patterns 728, and the substrate interconnection pattern 720, as described herein may be repeatedly performed to form the package substrate 700. Some of the uppermost ones of the substrate interconnection patterns 720 may be used as the substrate pads.

The solder resist pattern 750 may be formed to cover the uppermost ones of the substrate insulating patterns 710 and enclose the substrate pads.

Referring back to FIG. 17, in some embodiments, the first and second semiconductor chips 200 and 300 may be mounted on the package substrate 700. Thereafter, the carrier substrate 900 may be removed to expose the outer pads 740. The outer terminals 705 may be provided on the outer pads 740.

In a semiconductor package according to some embodiments of the present inventive concept, one or more thermoelectric patterns and at least one conductive pattern, which are used as a thermoelectric device, may be vertically arranged and aligned to each other, and thus, the thermoelectric device may occupy a small area. That is, it may be possible to reduce an area for the thermoelectric device and the overall size of the semiconductor package. In addition, the thermoelectric device may be provided to vertically penetrate a package substrate, and thus, the thermoelectric device may be easily used to transfer heat through the package substrate in a downward direction. As a result, a semiconductor package having improved heat-dissipation efficiency may be provided.

In a semiconductor package according to some embodiments of the present inventive concept, an internal interconnection line, which is provided in the package substrate and is used to supply an electric power to a semiconductor chip, may be used as a thermoelectric device for the heat-dissipation process, and the electric power supplied to the semiconductor chip may be used for a heat-dissipation operation of the thermoelectric device. No additional interconnection lines may be required to operate the thermoelectric device, and thus, it may be possible to reduce the overall size of the semiconductor package. In addition, the operations of the semiconductor chip and the thermoelectric device may be executed using the same electric power, and thus, the operation of the thermoelectric device may be actively executed, depending on the operation of the semiconductor chip. Thus, it may be possible to realize a semiconductor package having improved electrical and heat-dissipation characteristics.

As used herein, an element or region that is “covering” or “surrounding” or “filling” another element or region may completely or partially cover or surround or fill the other element or region.

Although terms (e.g., first, second or third) may be used herein to describe various elements, these elements should not be limited by these terms. These terms are only used to distinguish one element from another. For example, a first element may be referred to as a second element, and, similarly a second element may be referred to as a first element without departing from the teachings of the disclosure.

While example embodiments of the present inventive concept have been shown and described, it will be understood by one of ordinary skill in the art that variations in form and detail may be made therein without departing from the spirit and scope of the attached claims. The above-disclosed subject matter is to be considered illustrative, and not restrictive, and the appended claims are intended to cover all such modifications, enhancements, and other embodiments, which fall within the scope of the present inventive concept. Thus, to the maximum extent allowed by law, the scope is to be determined by the broadest permissible interpretation of the following claims and their equivalents, and shall not be restricted or limited by the foregoing detailed description.

What is claimed is:

1. A semiconductor package, comprising:
a package substrate;
a semiconductor chip mounted on the package substrate; and
at least two outer terminals provided below the package substrate,
wherein the at least two outer terminals comprise at least one signal terminal configured to deliver an operation signal to the semiconductor chip, and at least one power terminal configured to supply electrical power to the semiconductor chip,
wherein the package substrate comprises:
an insulating portion;
one or more interconnection patterns provided in the insulating portion to electrically connect the semiconductor chip to the at least one signal terminal; and
a heat-dissipation pattern provided in the insulating portion to electrically connect the semiconductor chip to the at least one power terminal,
wherein the heat-dissipation pattern comprises at least one conductive pattern and at least one thermoelectric pattern connected in series and extending in a direction from the at least one outer terminal toward the semiconductor chip,
wherein the at least one conductive pattern and the at least one thermoelectric pattern are alternately connected to each other, and
wherein the at least one thermoelectric pattern comprises an n-type semiconductor material.

2. The semiconductor package of claim 1, wherein the at least one conductive pattern and the one or more interconnection patterns comprise a same material.

3. The semiconductor package of claim 2, wherein the at least one conductive pattern and the one or more interconnection patterns comprise copper (Cu).

4. The semiconductor package of claim 1, wherein the at least one conductive pattern and the at least one thermoelectric pattern are stacked in a direction perpendicular relative to the package substrate.

5. The semiconductor package of claim 1, wherein the package substrate further comprises a substrate pad, wherein the semiconductor chip is mounted on, and
the heat-dissipation pattern is electrically connected to, the substrate pad.

6. The semiconductor package of claim 1, wherein the heat-dissipation pattern resides below the semiconductor chip.

7. The semiconductor package of claim 1, wherein the heat-dissipation pattern comprises a plurality of heat-dissipation patterns, each of the plurality of heat-dissipation patterns are horizontally spaced apart from each other, and
vertically penetrate the insulating portion.

8. The semiconductor package of claim 7, wherein a lowermost one of the at least one conductive pattern in each of the plurality of heat-dissipation patterns extends horizontally and connected to the at least one power terminal.

9. The semiconductor package of claim 1, wherein the heat-dissipation pattern further comprises a capacitor pattern electrically connected to the at least one conductive pattern.

10. The semiconductor package of claim 1, wherein the heat-dissipation pattern further comprises one or more contact patterns interposed between the at least one conductive pattern and the at least one thermoelectric pattern, and
the one or more contact patterns comprise nickel (Ni) or gold (Au).

11. A semiconductor package, comprising:
a package substrate;
a semiconductor chip mounted on the package substrate; and
one or more outer terminals provided below the package substrate,
wherein the package substrate comprises:
an insulating portion;
a plurality of first pads provided on a top surface of the insulating portion, the semiconductor chip being mounted on the plurality of first pads;
a plurality of second pads and a third pad provided on a bottom surface of the insulating portion and coupled to the one or more outer terminals;
one or more interconnection patterns provided in the insulating portion to connect the plurality of first pads to the plurality of second pads; and
a heat-dissipation pattern disposed in the insulating portion and on the third pad,
wherein the heat-dissipation pattern comprises at least one conductive pattern and at least one thermoelectric pattern, vertically and alternately stacked on the third pad,
wherein the at least one conductive pattern comprises a same material as the one or more interconnection patterns, and
wherein an end portion of the heat-dissipation pattern residing adjacent to the semiconductor chip is configured to be cooled when a voltage is applied to the third pad.

12. The semiconductor package of claim 11, wherein the one or more interconnection patterns comprise at least one signal interconnection pattern configured to deliver an operation signal to the semiconductor chip, and at least one power interconnection pattern configured to supply electrical power to the semiconductor chip, and
wherein the heat-dissipation pattern is electrically disconnected from the one or more interconnection patterns and the semiconductor chip.

13. The semiconductor package of claim 12, wherein the at least one thermoelectric pattern comprises one of n- and p-type semiconductor materials.

14. The semiconductor package of claim 11, wherein the one or more interconnection patterns comprise at least one signal interconnection pattern configured to deliver an operation signal to the semiconductor chip, and
wherein the heat-dissipation pattern comprises at least one power interconnection pattern configured to supply electrical power to the semiconductor chip.

15. The semiconductor package of claim 14, wherein the at least one thermoelectric pattern comprises an n-type semiconductor material.

16. The semiconductor package of claim 14, wherein the heat-dissipation pattern resides below the semiconductor chip.

17. The semiconductor package of claim 11, wherein the heat-dissipation pattern further comprises a capacitor pattern electrically connected to at least one of the conductive patterns.

18. The semiconductor package of claim 11, wherein the heat-dissipation pattern comprises a plurality of heat-dissipation patterns, each heat-dissipation pattern being horizontally spaced apart from each other and
electrically connected to the third pad.

19. The semiconductor package of claim 11, wherein the at least one conductive pattern and the one or more interconnection patterns comprise copper (Cu).

20. A semiconductor package, comprising:
a package substrate;
an interposer substrate disposed on the package substrate;
a first semiconductor chip mounted on the interposer substrate; and
a chip stack provided on the interposer substrate and spaced apart from the first semiconductor chip, the chip stack comprising a plurality of second semiconductor chips vertically stacked on the interposer substrate,
wherein the interposer substrate comprises:
one or more interconnection patterns configured to deliver an operation signal from the package substrate to the first semiconductor chip and the chip stack;
one or more heat-dissipation patterns configured to deliver electrical power from the package substrate to the first semiconductor chip or the chip stack, the one or more heat-dissipation patterns comprising at least one conductive pattern and at least one thermoelectric pattern, alternately connected in series in a direction perpendicular relative to the interposer substrate; and
a capacitor pattern electrically connected to the at least one conductive pattern,
wherein the at least one conductive pattern comprises a same material as the one or more interconnection patterns, and
wherein the at least one thermoelectric pattern comprises an n-type semiconductor material.
